(19) United States
(12) Patent Application Publication
(10) Pub. No.: US 2024/0310727 A1
(43) Pub. Date: Sep. 19, 2024

(54) RESIST COMPOSITION AND PATTERN FORMING PROCESS

(71) Applicant: Shin-Etsu Chemical Co., Ltd., Tokyo (JP)

(72) Inventor: Jun Hatakeyama, Joetsu-shi (JP)

(73) Assignee: Shin-Etsu Chemical Co., Ltd., Tokyo (JP)

(21) Appl. No.: 18/590,436

(22) Filed: Feb. 28, 2024

(30) Foreign Application Priority Data
Mar. 7, 2023 (JP) 2023-034211

(51) Int. Cl. G03F 7/029; G03F 7/004; G03F 7/038; G03F 7/039; G03F 7/20

(52) U.S. Cl. CPC G03F 7/029; G03F 7/0045; G03F 7/0048; G03F 7/0382; G03F 7/0388; G03F 7/0397; G03F 7/2004

(57) ABSTRACT

The present invention relates to a resist composition and a pattern forming process. The quencher is capable of improving the LWR of line patterns or the dimensional uniformity (CDU) of hole patterns and enhancing sensitivity. The resist composition comprises a quencher containing a sulfonium salt of a benzoic acid which is substituted with a C₂-C₁₄ hydrocarbyloxy group having a trifluoromethyl group.

### CROSS-REFERENCE TO RELATED APPLICATIONS

This non-provisional application claims priority under 35 U.S.C. § 119(a) on Patent Application No. 2023-034211 filed in Japan on Mar. 7, 2023, the entire contents of which are hereby incorporated by reference.

### TECHNICAL FIELD

The present invention relates to a resist composition and a pattern forming process.

### BACKGROUND ART

To meet the demand for higher integration density and higher operating speed of LSIs, the effort to reduce the pattern rule is in rapid progress. As the use of 5G high-speed communications and artificial intelligence (AI) is widely spreading, high-performance devices are needed for their processing. As the most advanced miniaturization technology, mass production of microelectronic devices at the 5-nm node by the lithography using extreme ultraviolet (EUV) having a wavelength of 13.5 nm has been implemented. Studies are made on the application of EUV lithography to 3-nm node devices of the next generation and 2-nm node devices of the next-but-one generation.

As the feature size reduces, image blurs due to acid diffusion become a problem. To ensure resolution for fine patterns of sub-45-nm size, not only an improvement in dissolution contrast is important as previously reported, but also the control of acid diffusion is important as reported in Non-Patent Document 1. Since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

A triangular tradeoff relationship among sensitivity, resolution, and edge roughness (LWR) has been pointed out. Specifically, a resolution improvement requires to reduce acid diffusion whereas a short acid diffusion distance leads to a reduction of sensitivity.

The addition of an acid generator capable of generating a bulky acid is an effective means for reducing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond and capable of generating a specific sulfonic acid. Patent Document 2 discloses a sulfonium salt having a sulfonic acid directly bonded to the backbone.

An acid labile group used in a (meth)acrylate polymer for an ArF resist composition undergoes a deprotection reaction by use of a photoacid generator that generates a sulfonic acid having a fluorine atom substituted at the α-position, but the deprotection reaction does not proceed by an acid generator that generates a sulfonic acid not having a fluorine atom substituted at the α-position or a carboxylic acid. When a sulfonium salt or an iodonium salt that generates a sulfonic acid having a fluorine atom substituted at the α-position is mixed with a sulfonium salt or an iodonium salt that generates a sulfonic acid not having a fluorine atom substituted at the α-position, the sulfonium salt or iodonium salt that generates a sulfonic acid not having a fluorine atom substituted at the α-position undergoes ion exchange with a sulfonic acid having a fluorine atom substituted at the α-position. Since the sulfonic acid having a fluorine atom substituted at the α-position, which is generated by light, is returned to a sulfonium salt or an iodonium salt by ion exchange, a sulfonium salt or an iodonium salt of a sulfonic acid not having a fluorine atom substituted at the α-position or a carboxylic acid functions as a quencher. A resist composition containing a sulfonium salt or an iodonium salt that generates a carboxylic acid as a quencher has been proposed in Patent Document 3.

Sulfonium salt type quenchers capable of generating various carboxylic acids have been proposed. In particular, sulfonium salts of salicylic acid and β-hydroxycarboxylic acid (Patent Document 4), salicylic acid derivatives (Patent Documents 5 and 6), fluorosalicylic acid (Patent Document 7), and hydroxynaphthoic acid (Patent Document 8) have been proposed. In particular, salicylic acid has an effect of reducing acid diffusion by an intramolecular hydrogen bond between a carboxylic acid and a hydroxy group.

It is pointed out that aggregation of the quencher decreases the dimensional uniformity of the resist pattern. It is expected to prevent aggregation of the quencher in the resist film and make the distribution of the quencher uniform to improve the dimensional uniformity of the developed pattern.

### CITATION LIST

Patent Document 1: JP-A 2006-045311
Patent Document 2: JP-A 2006-178317
Patent Document 3: JP-A 2007-114431
Patent Document 4: WO 2018/159560
Patent Document 5: JP-A 2020-203984
Patent Document 6: JP-A 2020-091404
Patent Document 7: JP-A 2020-091312
Patent Document 8: JP-A 2019-120760
Non-Patent Document 1: SPIE Vol. 6520 65203L-1 (2007)

### SUMMARY OF THE INVENTION

For resist compositions, it is desired to develop a quencher capable of improving the LWR of line patterns or the dimensional uniformity (CDU) of hole patterns and enhancing sensitivity. For this purpose, it is necessary to further reduce image blurs due to diffusion.

The present invention has been made in view of the above circumstances, and an object of the present invention is to provide a resist composition that exhibits higher sensitivity and improved LWR and CDU regardless of whether it is of positive or negative tone, and a pattern forming process using the resist composition.

As a result of intensive studies to achieve the above object, the present inventor has found that a sulfonium salt of a benzoic acid which is substituted with a C₂-C₁₄ hydrocarbyloxy group having a trifluoromethyl group serves as a quencher that reduces acid diffusion, and exhibits an excellent effect of reducing acid diffusion, and an effect of preventing aggregation of the quencher due to electron repulsion of the bulky C₂-C₁₄ hydrocarbyloxy group having a trifluoromethyl group, so that the LWR and CDU are improved, and a resist composition having excellent resolution and a wide process margin is obtained, thereby completing the present invention.

That is, the present invention provides the following resist composition and pattern forming process.
1. A resist composition comprising a quencher containing a sulfonium salt of a benzoic acid which is substituted with a C₂-C₁₄ hydrocarbyloxy group having a trifluoromethyl group.
2. The resist composition of item 1, wherein the sulfonium salt has formula (1):

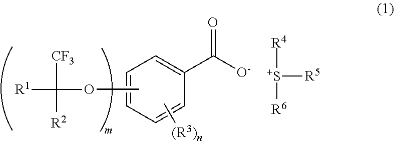

wherein m is 1 or 2, and n is an integer of 0 to 2,
R¹ is a hydrogen atom, a C₁-C₁₂ aliphatic hydrocarbyl group, or a C₆-C₁₀ aryl group, some or all of hydrogen atoms of the aliphatic hydrocarbyl group and the aryl group may be substituted with a halogen atom, a trifluoromethyl group, or a trifluoromethoxy group, and some of —CH₂— of the aliphatic hydrocarbyl group may be substituted with an ether bond or an ester bond,
R² is a hydrogen atom, a C₁-C₄ alkyl group, or a trifluoromethyl group,
R³ is a halogen atom, a trifluoromethyl group, a cyano group, a nitro group, a hydroxy group, a C₁-C₁₂ hydrocarbyloxy group, a C₂-C₁₂ hydrocarbyloxycarbonyl group, a C₂-C₁₂ hydrocarbylcarbonyloxy group, a C₂-C₁₂ hydrocarbyloxycarbonyloxy group, or a substituted or unsubstituted amino group, and
R⁴ to R⁶ are each independently a halogen atom or a C₁-C₂₀ hydrocarbyl group which may contain a heteroatom, and R⁴ and R⁵ may bond together to form a ring with a sulfur atom to which they are bonded.
3. The resist composition of item 1 or 2, further comprising a base polymer.
4. The resist composition of item 3, wherein the base polymer contains repeat units having formula (a1) or repeat units having formula (a2):

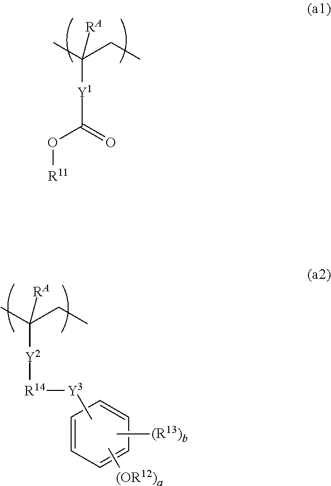

wherein R^{A} is each independently a hydrogen atom or a methyl group,
Y¹ is a single bond, a phenylene group, a naphthylene group, or a C₁-C₁₂ linking group containing at least one moiety selected from an ester bond and a lactone ring,
Y² is a single bond or an ester bond,
Y³ is a single bond, an ether bond, or an ester bond,
R¹¹ and R¹² are each independently an acid labile group,
R¹³ is a fluorine atom, a trifluoromethyl group, a cyano group, or a C₁-C₆ saturated hydrocarbyl group,
R¹⁴ is a single bond or a C₁-C₆ alkanediyl group in which some constituent —CH₂— may be substituted with an ether bond or an ester bond, and
a is 1 or 2, and b is an integer of 0 to 4, provided that 1≤a+b≤5.
5. The resist composition of item 4, which is a chemically amplified positive resist composition.
6. The resist composition of item 3, wherein the base polymer is free of an acid labile group.
7. The resist composition of item 6, which is a chemically amplified negative resist composition.
8. The resist composition of any one of items 3 to 7, wherein the base polymer contains at least one kind selected from repeat units having formulae (f1) to (f3):

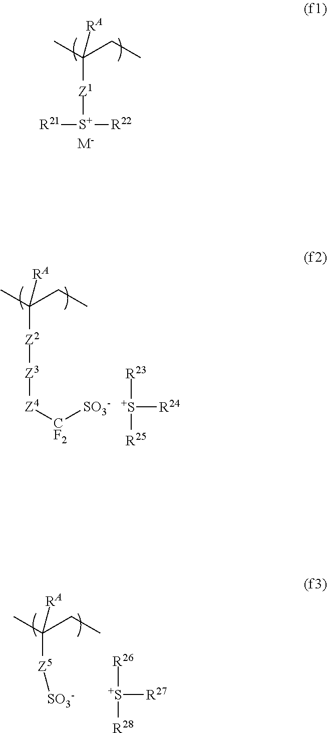

wherein R^{A} is each independently a hydrogen atom or a methyl group,
Z¹ is a single bond, a C₁-C₆ aliphatic hydrocarbylene group, a phenylene group, a naphthylene group, a C₇-C₁₈ group obtained by combining the foregoing, —O—Z¹¹—, —C(═O)—O—Z¹¹—, or —C(═O)—NH—Z¹¹—, wherein Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group,
Z² is a single bond or an ester bond,
Z³ is a single bond, —Z³¹—C(═O)—O—, —Z³¹—O—, or —Z³¹—O—C(═O)—, wherein Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom,
Z⁴ is a methylene group, a 2,2,2-trifluoro-1,1-ethanediyl group, or a carbonyl group,
Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—, wherein Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a halogen atom, or a hydroxy group,
R²¹ to R²⁸ are each independently a halogen atom or a C₁-C₂₀ hydrocarbyl group which may contain a heteroatom, and R²³ and R²⁴ or R²⁶ and R²⁷ may bond together to form a ring with a sulfur atom to which they are bonded, and
M⁻ is a non-nucleophilic counter ion.
9. The resist composition of any one of items 1 to 8, further comprising an acid generator that generates a strong acid.
10. The resist composition of item 9, wherein the acid generator generates a sulfonic acid, an imide acid, or a methide acid.
11. The resist composition of any one of items 1 to 10, further comprising an organic solvent.
12. The resist composition of any one of items 1 to 11, further comprising a surfactant.
13. A pattern forming process comprising the steps of:
applying the resist composition of any one of items 1 to 12 onto a substrate to form a resist film on the substrate,
exposing the resist film to high-energy radiation, and
developing the exposed resist film in a developer.
14. The pattern forming process of item 13, wherein the high-energy radiation is KrF excimer laser, ArF excimer laser, electron beam (EB), or EUV having a wavelength of 3 to 15 nm.

### Advantageous Effects of Invention

The sulfonium salt of a benzoic acid which is substituted with a C₂-C₁₄ hydrocarbyloxy group having a trifluoromethyl group serves as a quencher that reduces acid diffusion. This makes it possible to form a resist composition reduced in acid diffusion and having low LWR and improved CDU.

### DETAILED DESCRIPTION OF THE INVENTION

### [Resist Composition]

The resist composition of the present invention contains a quencher containing a sulfonium salt of a benzoic acid which is substituted with a C₂-C₁₄ hydrocarbyloxy group having a trifluoromethyl group.

### [Quencher]

The sulfonium salt of a benzoic acid which is substituted with a C₂-C₁₄ hydrocarbyloxy group having a trifluoromethyl group preferably has formula (1).

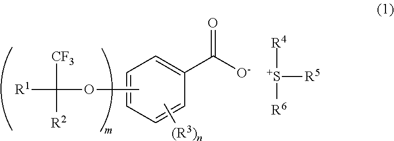

In formula (1), m is 1 or 2, and n is an integer of 0 to 2.

In formula (1), R¹ is a hydrogen atom, a C₁-C₁₂ aliphatic hydrocarbyl group, or a C₆-C₁₀ aryl group, some or all of hydrogen atoms of the aliphatic hydrocarbyl group and the aryl group may be substituted with a halogen atom, a trifluoromethyl group, or a trifluoromethoxy group, and some of —CH₂— of the aliphatic hydrocarbyl group may be substituted with an ether bond or an ester bond.

The C₁-C₁₂ aliphatic hydrocarbyl group represented by R¹ may be saturated or unsaturated, and may be linear, branched, or cyclic. Specific examples thereof include C₁-C₁₂ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a neopentyl group, a n-hexyl group, a n-heptyl group, a n-octyl group, a n-nonyl group, and a n-decyl group; C₃-C₁₂ cyclic saturated hydrocarbon groups such as a cyclopropyl group, a cyclobutyl group, a cyclopentyl group, a cyclohexyl group, a norbornyl group, and an adamantyl group; C₂-C₁₂ alkenyl groups such as an ethenyl group, a 1-propenyl group, a 2-propenyl group, a 1-methyl-1-ethenyl group, a 1-butenyl group, a 2-butenyl group, and a 3-butenyl group; C₂-C₁₂ alkynyl groups such as an ethynyl group, a 1-propynyl group, a 2-propynyl group, a 1-butynyl group, a 2-butynyl group, and a 3-butynyl group; C₃-C₁₂ cyclic unsaturated hydrocarbyl groups such as a 1-cycloallyl group, a 1-cyclobutenyl group, a 1-cyclopentenyl group, a 2-cyclopentenyl group, a 3-cyclopentenyl group, a 1-cyclohexenyl group, a 2-cyclohexenyl group, and a 3-cyclohexenyl group; and groups obtained by combining the foregoing.

Examples of the C₆-C₁₀ aryl group represented by R¹ include a phenyl group, a 1-naphthyl group, and a 2-naphthyl group.

In formula (1), R² is a hydrogen atom, a C₁-C₄ alkyl group, or a trifluoromethyl group. Examples of the alkyl group include a methyl group, an ethyl group, a n-propyl group, an isopropyl group, a n-butyl group, an isobutyl group, a sec-butyl group, and a tert-butyl group.

In formula (1), R³ is a halogen atom, a trifluoromethyl group, a cyano group, a nitro group, a hydroxy group, a C₁-C₁₂ hydrocarbyloxy group, a C₂-C₁₂ hydrocarbyloxycarbonyl group, a C₂-C₁₂ hydrocarbylcarbonyloxy group, a C₂-C₁₂ hydrocarbyloxycarbonyloxy group, or a substituted or unsubstituted amino group.

Examples of the halogen atom represented by R³ include a fluorine atom, a chlorine atom, a bromine atom, and an iodine atom.

The hydrocarbyl moiety in the C₁-C₁₂ hydrocarbyloxy group, the C₂-C₁₂ hydrocarbyloxycarbonyl group, the C₂-C₁₂ hydrocarbylcarbonyloxy group, and the C₂-C₁₂ hydrocarbyloxycarbonyloxy group represented by R³ may be saturated or unsaturated, and may be linear, branched, or cyclic. Specific examples thereof include C₁-C₁₂ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a neopentyl group, a n-hexyl group, a n-heptyl group, a n-octyl group, a n-nonyl group, and a n-decyl group; C₃-C₁₂ cyclic saturated hydrocarbon groups such as a cyclopropyl group, a cyclobutyl group, a cyclopentyl group, a cyclohexyl group, a norbornyl group, and an adamantyl group; C₂-C₁₂ alkenyl groups such as an ethenyl group, a 1-propenyl group, a 2-propenyl group, a 1-methyl-1-ethenyl group, a 1-butenyl group, a 2-butenyl group, and a 3-butenyl group; C₂-C₁₂ alkynyl groups such as an ethynyl group, a 1-propynyl group, a 2-propynyl group, a 1-butynyl group, a 2-butynyl group, and a 3-butynyl group; C₃-C₁₂ cyclic unsaturated hydrocarbyl groups such as a 1-cycloallyl group, a 1-cyclobutenyl group, a 1-cyclopentenyl group, a 2-cyclopentenyl group, a 3-cyclopentenyl group, a 1-cyclohexenyl group, a 2-cyclohexenyl group, and a 3-cyclohexenyl group; C₆-C₁₂ aryl groups such as a phenyl group, a 1-naphthyl group, and a 2-naphthyl group; C₇-C₁₂ aralkyl groups such as a benzyl group and a phenethyl group; and groups obtained by combining the foregoing.

Examples of the substituted or unsubstituted amino group represented by R³ include those represented by, for example, —N(R^{3A})(R^{3B}), N(R^{3C})—C(═O)—R^{3D}, N(R^{3C})—C(═O)—O—R^{3D}, and —N(R^{3C})—S(═O)₂—R^{3D}. Here, R^{3A}, R^{3B}, R^{3C}, and R^{3D} are each independently a C₁-C₁₂ hydrocarbyl group which may be substituted with a halogen atom. The hydrocarbyl group may be saturated or unsaturated, and may be linear, branched, or cyclic. Specific examples thereof include those described above.

Examples of an anion of the sulfonium salt having formula (1) include those shown below, but are not limited thereto.

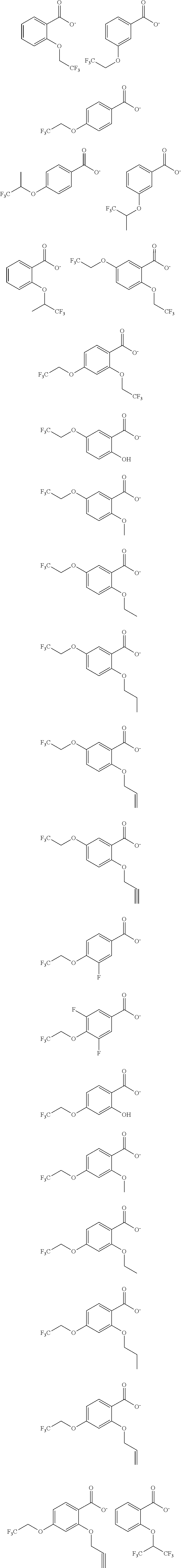

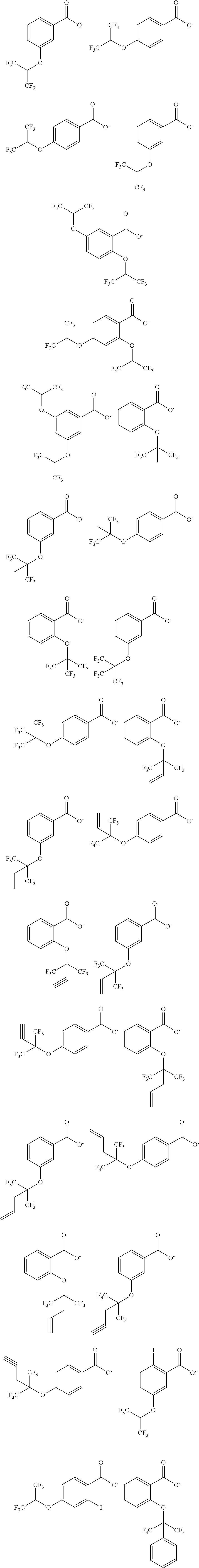

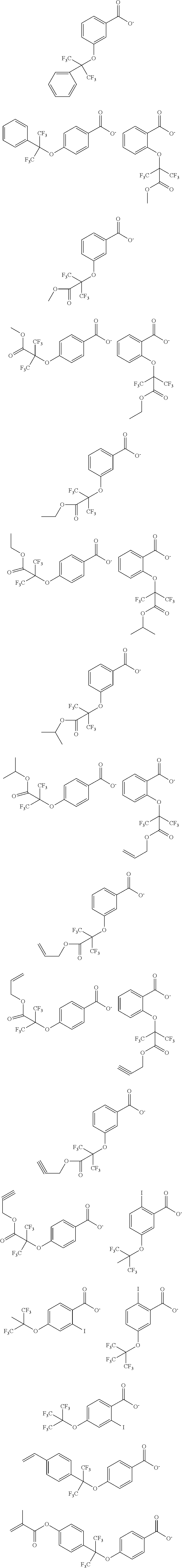

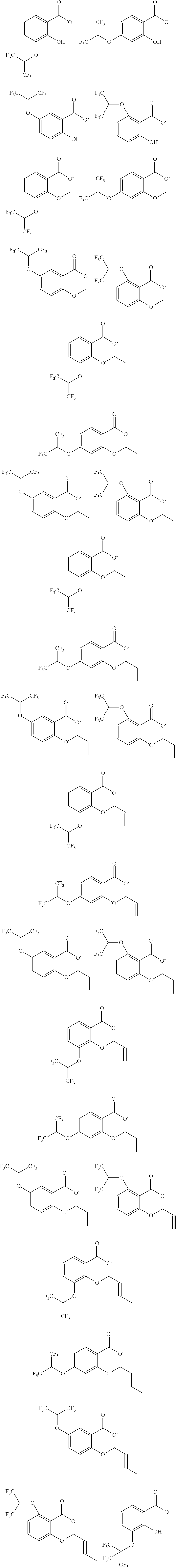

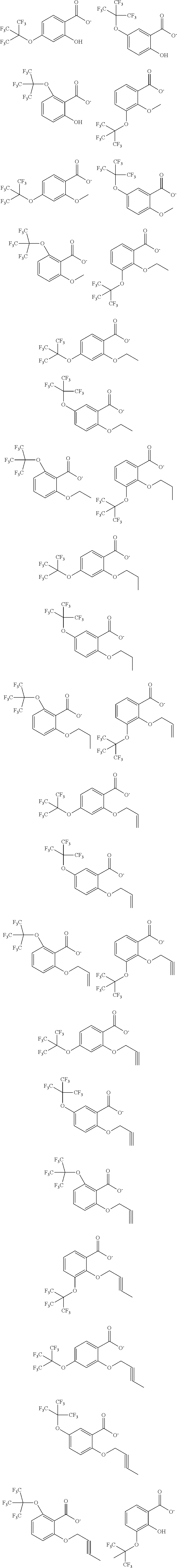

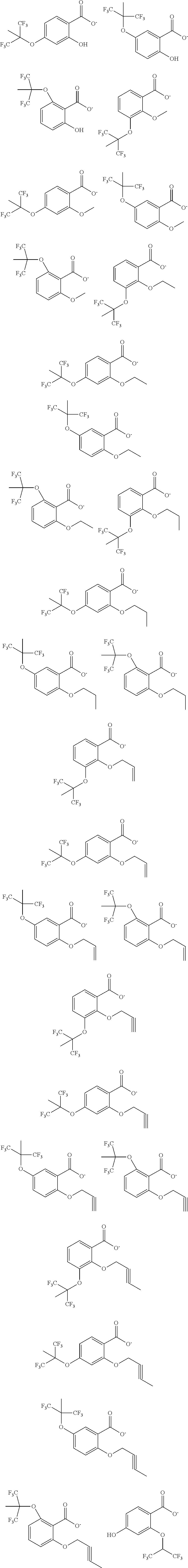

[chemical structure]

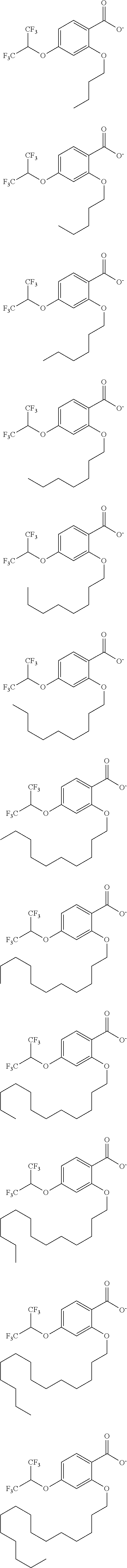

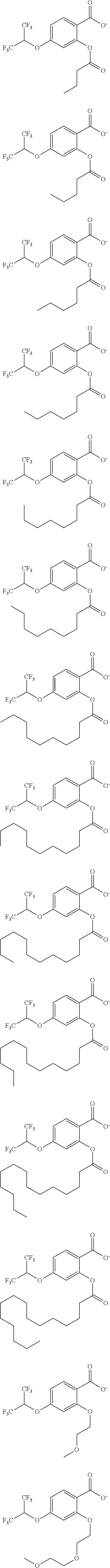

[chemical structure]

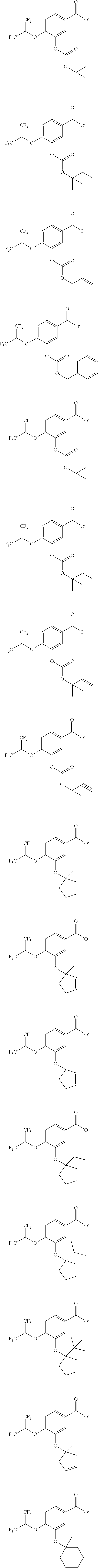

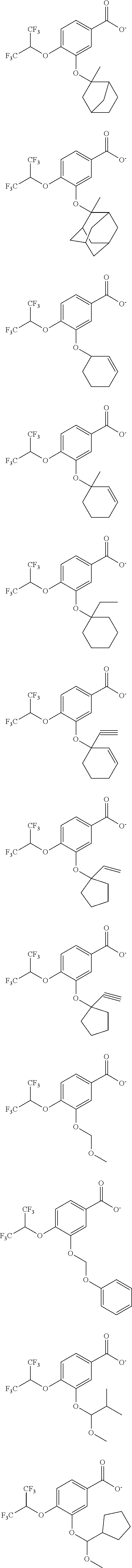

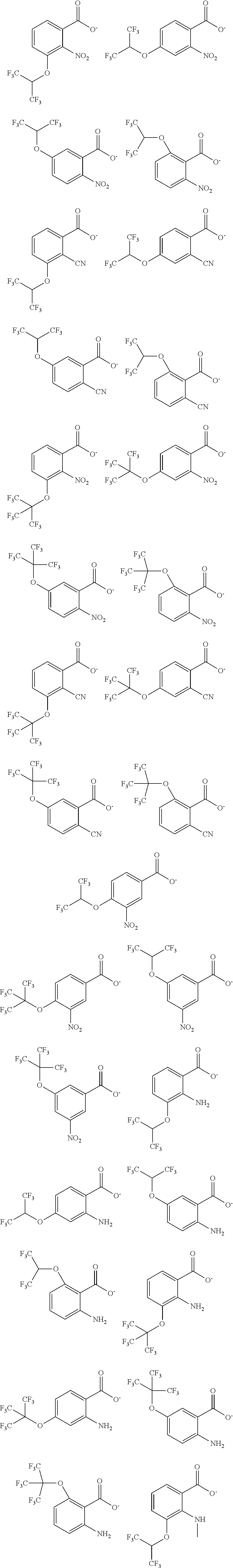

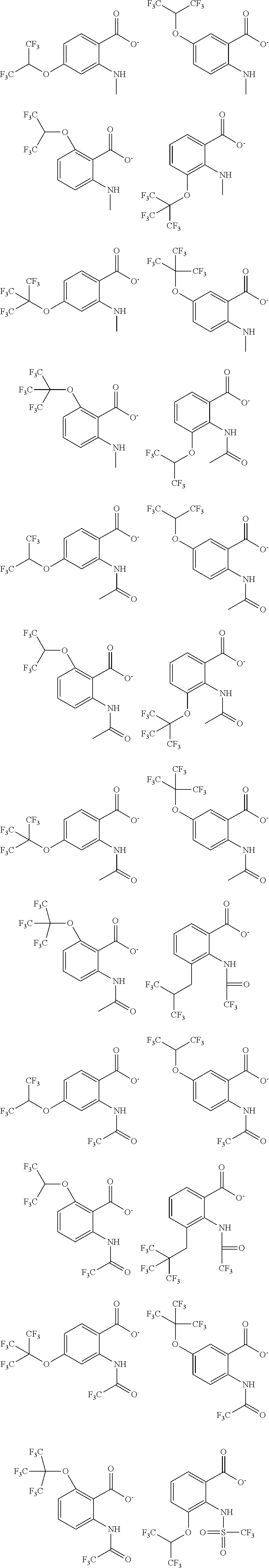

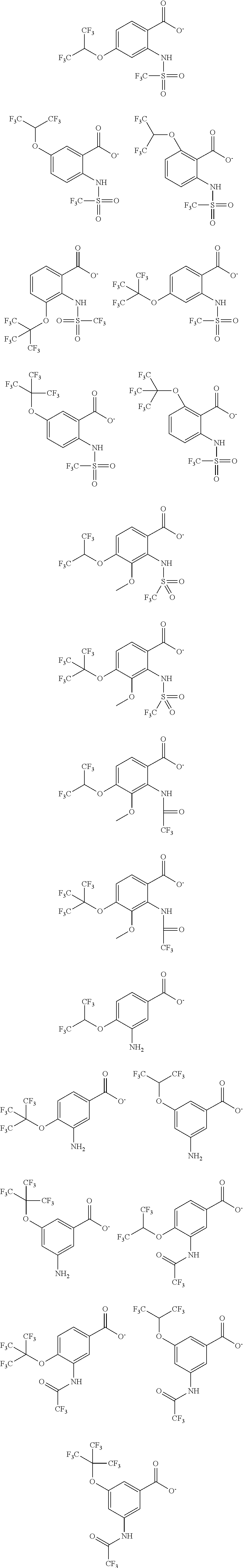

In formula (1), R⁴ to R⁶ are each independently a halogen atom or a C₁-C₂₀ hydrocarbyl group which may contain a heteroatom.

Examples of the halogen atom represented by R⁴ to R⁶ include a fluorine atom, a chlorine atom, a bromine atom, and an iodine atom.

The C₁-C₂₀ hydrocarbyl group represented by R⁴ to R⁶ may be saturated or unsaturated, and may be linear, branched, or cyclic. Specific examples thereof include C₁-C₂₀ alkyl groups such as a methyl group, an ethyl group, a n-propyl group, an isopropyl group, a n-butyl group, an isobutyl group, a sec-butyl group, a tert-butyl group, a n-pentyl group, a n-hexyl group, a n-octyl group, a n-nonyl group, a n-decyl group, an undecyl group, a dodecyl group, a tridecyl group, a tetradecyl group, a pentadecyl group, a heptadecyl group, an octadecyl group, a nonadecyl group, and an icosyl group; C₃-C₂₀ cyclic saturated hydrocarbyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; C₂-C₂₀ alkenyl groups such as a vinyl group, a propenyl group, a butenyl group, and a hexenyl group; C₂-C₂₀ alkynyl groups such as an ethynyl group, a propynyl group, and a butynyl group; C₃-C₂₀ cyclic unsaturated aliphatic hydrocarbyl groups such as a cyclohexenyl group and a norbornenyl group; C₆-C₂₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, and a tert-butylnaphthyl group; C₇-C₂₀ aralkyl groups such as a benzyl group and a phenethyl group; and groups obtained by combining the foregoing.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a mercapto group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group.

R⁴ and R⁵ may bond together to form a ring with a sulfur atom to which they are bonded. The ring preferably has the following structure.

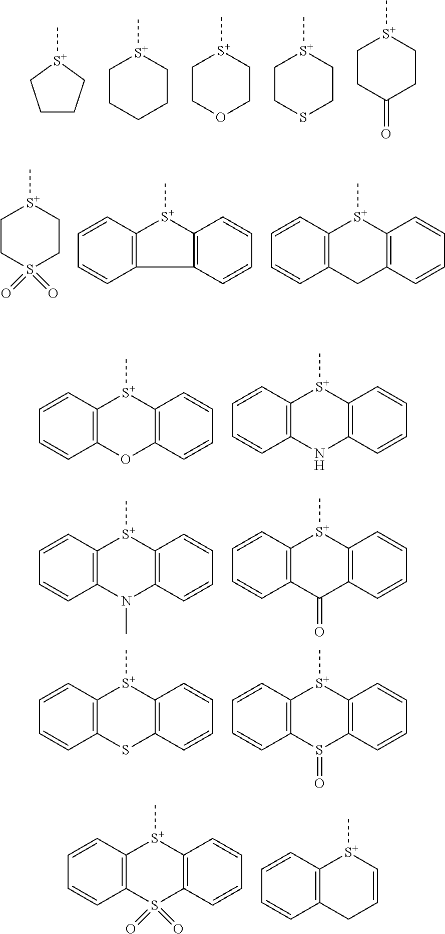

In the formulae, a broken line designates a bond with R⁶.

Examples of a cation of the sulfonium salt having formula (1) include those shown below, but are not limited thereto.

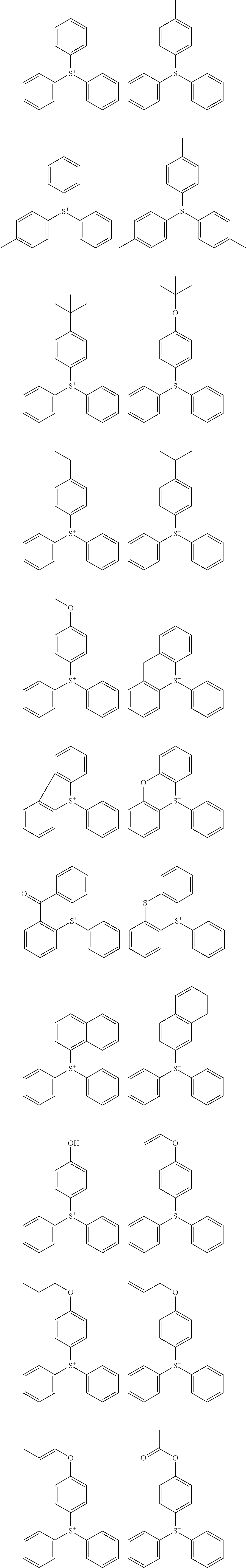

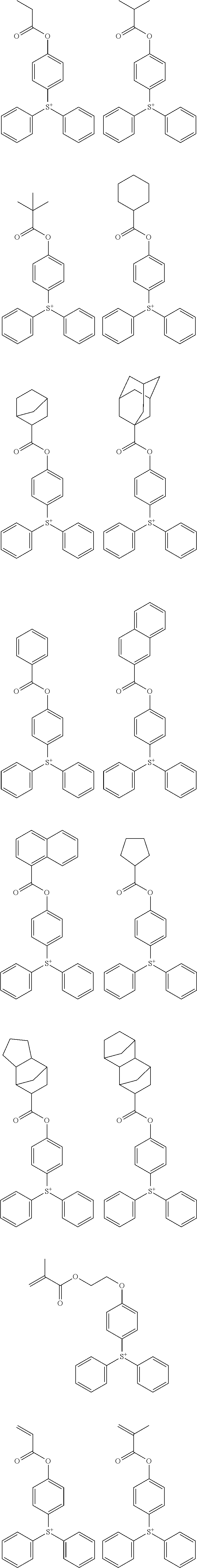

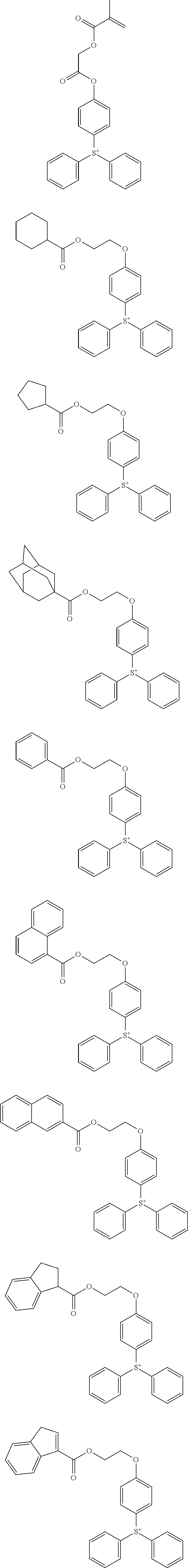

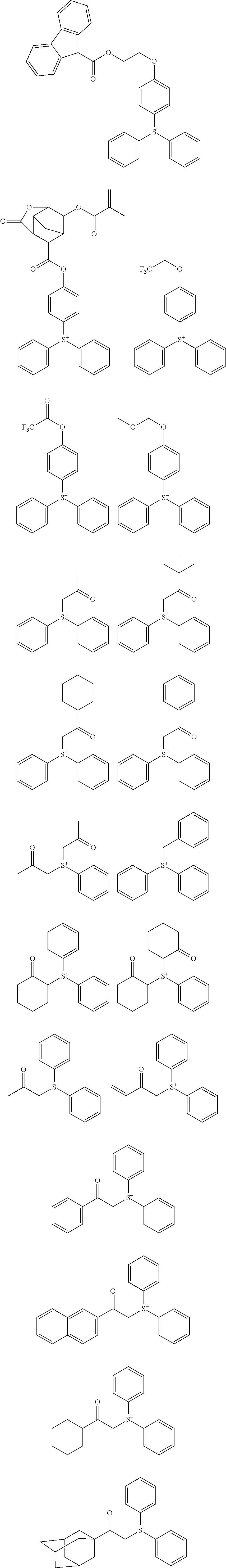

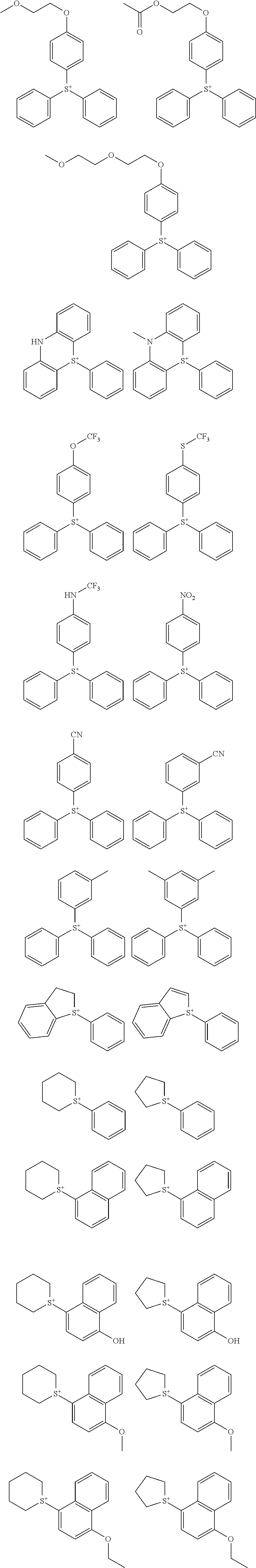

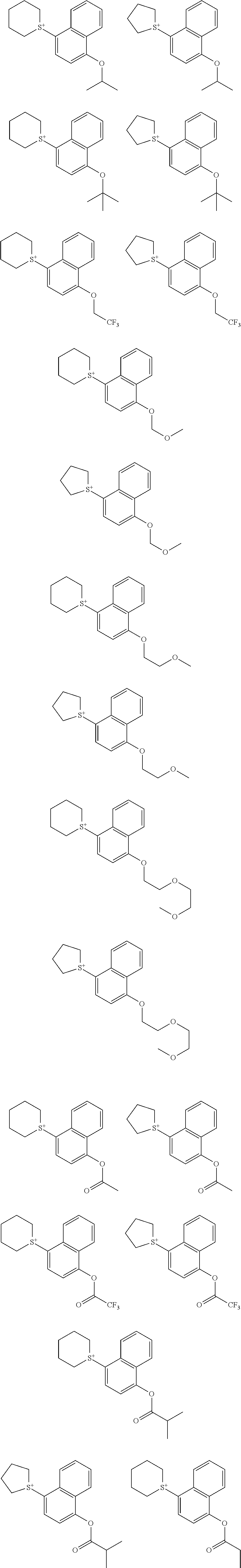

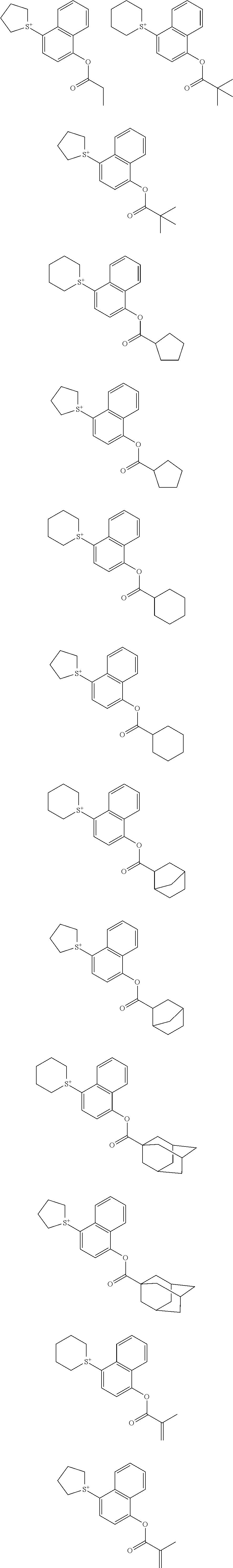

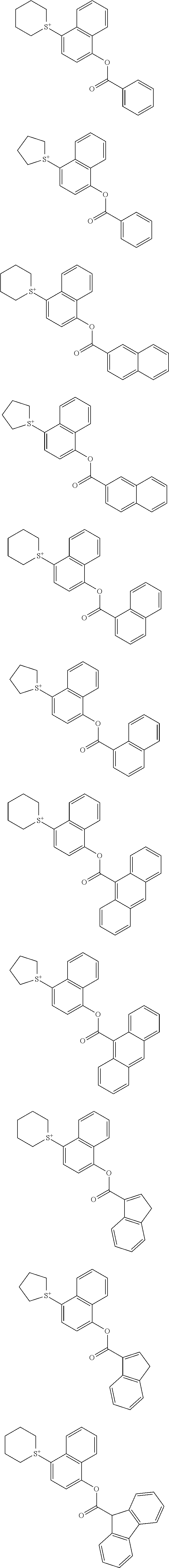

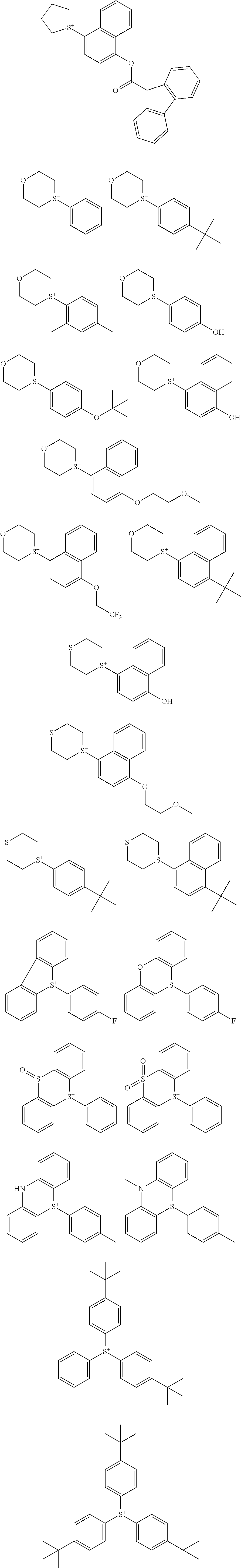

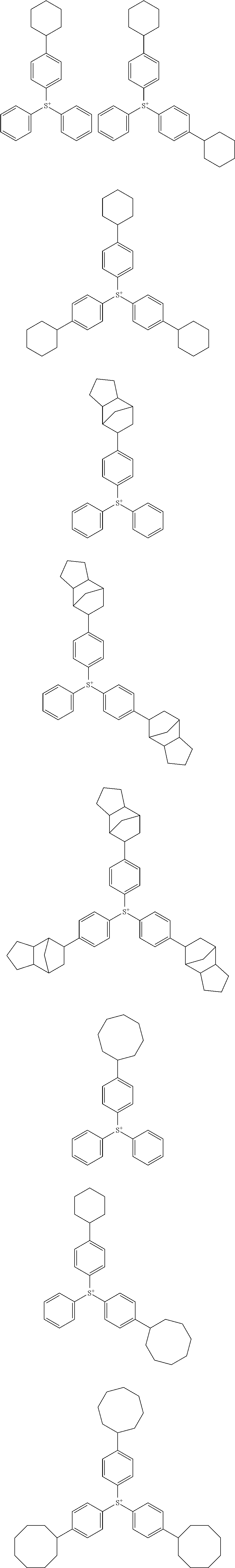

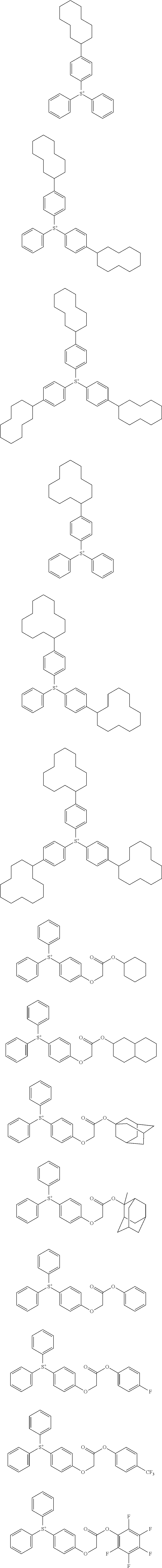

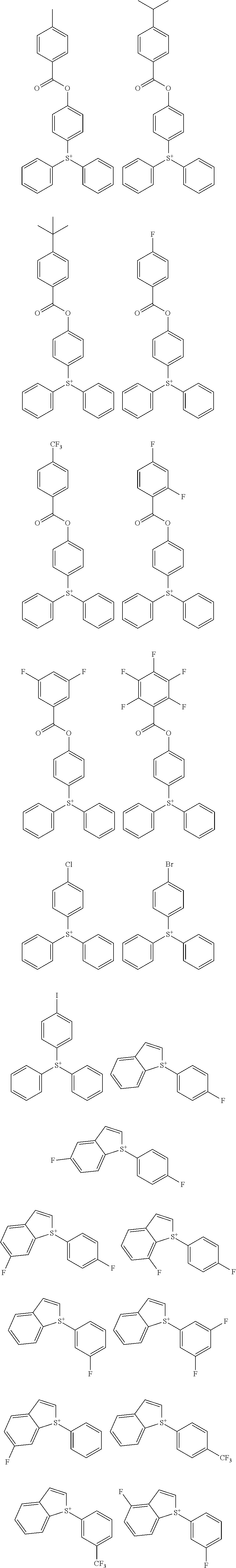

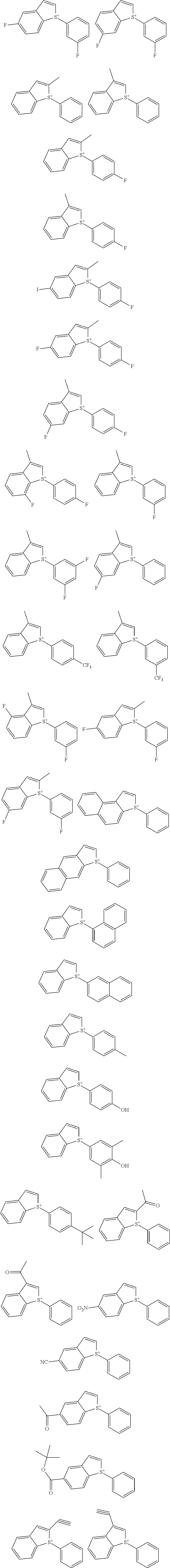

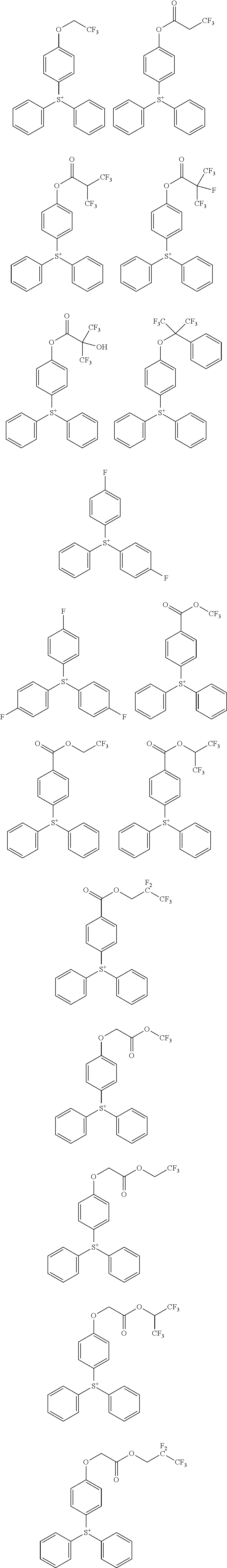

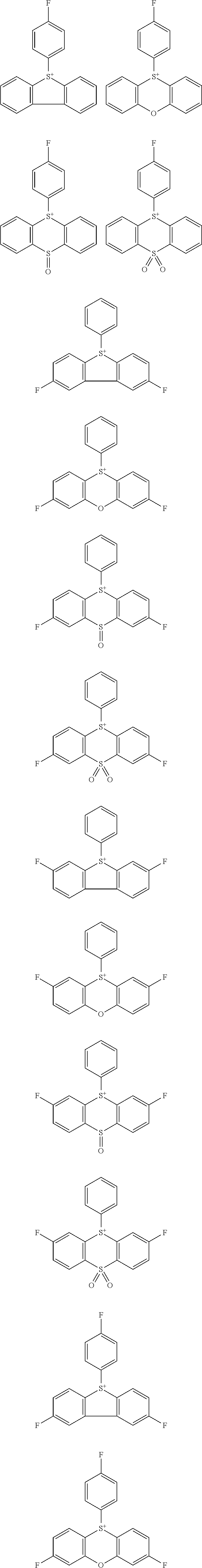

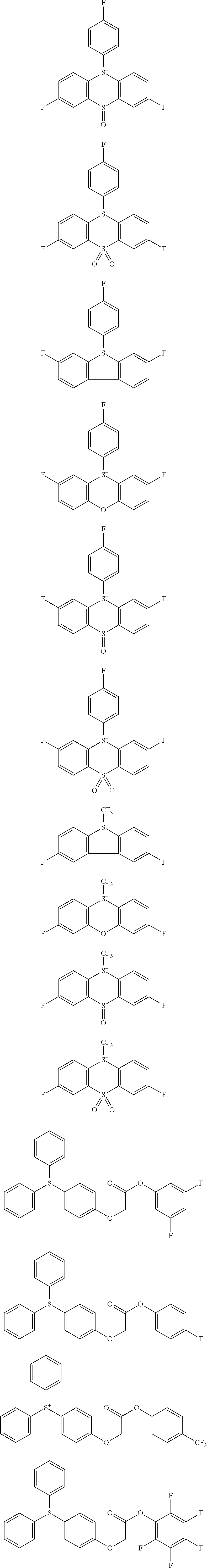

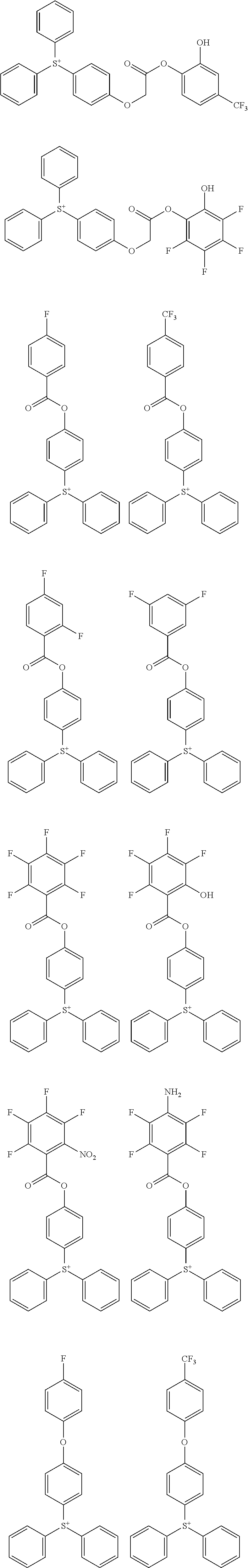

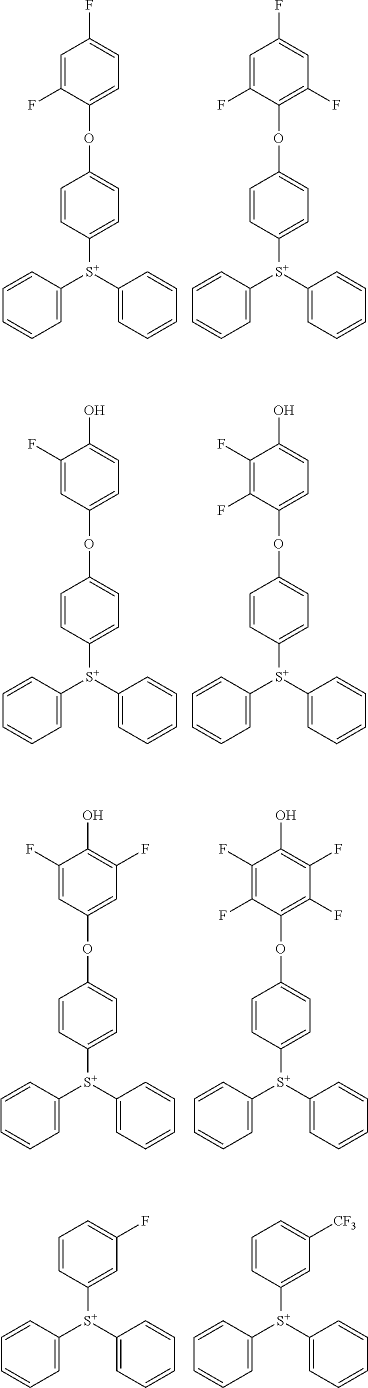

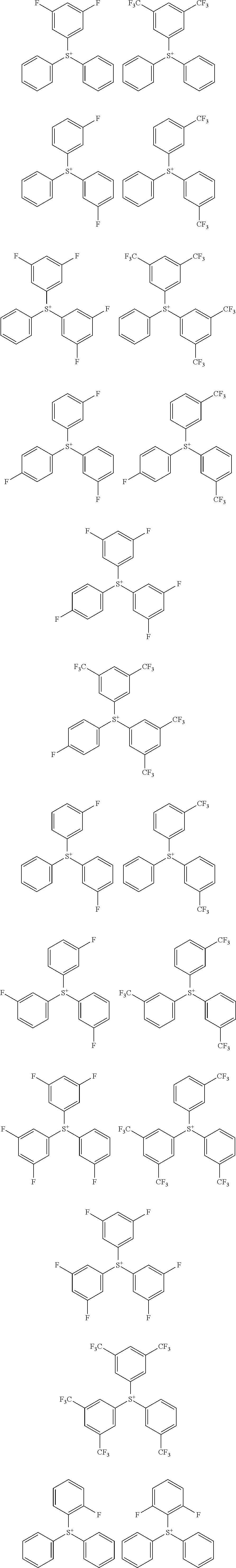

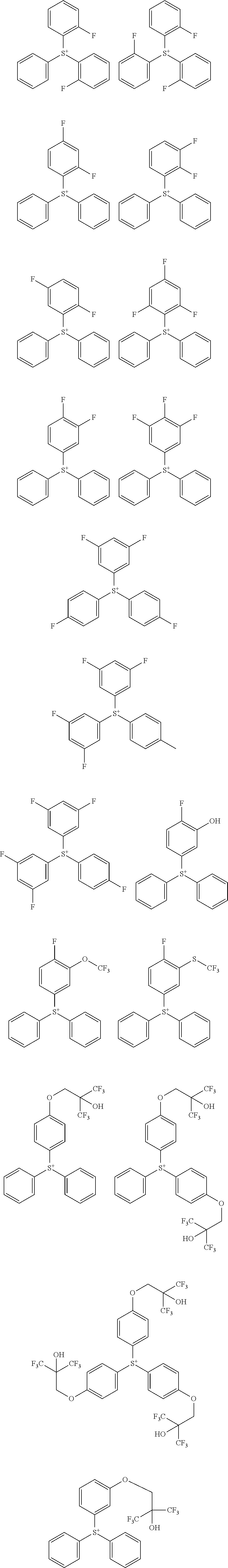

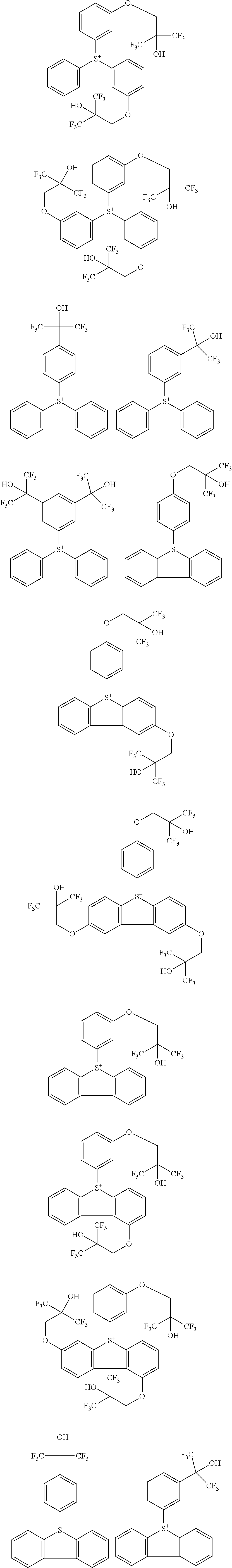

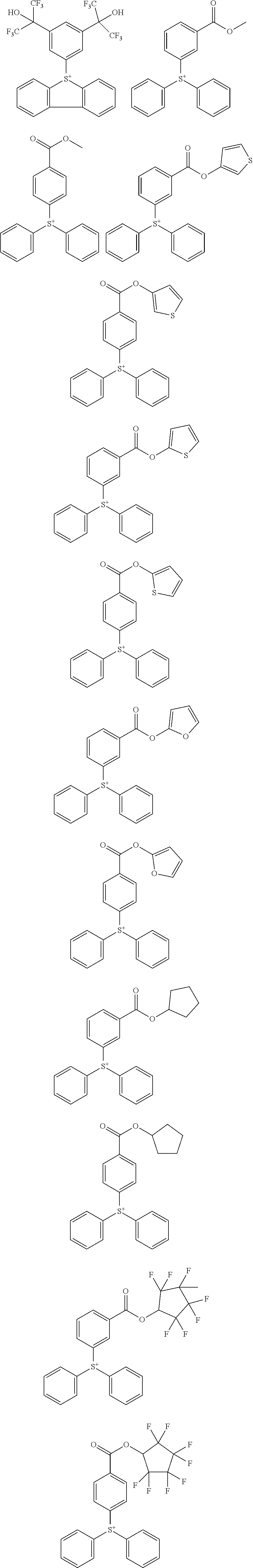

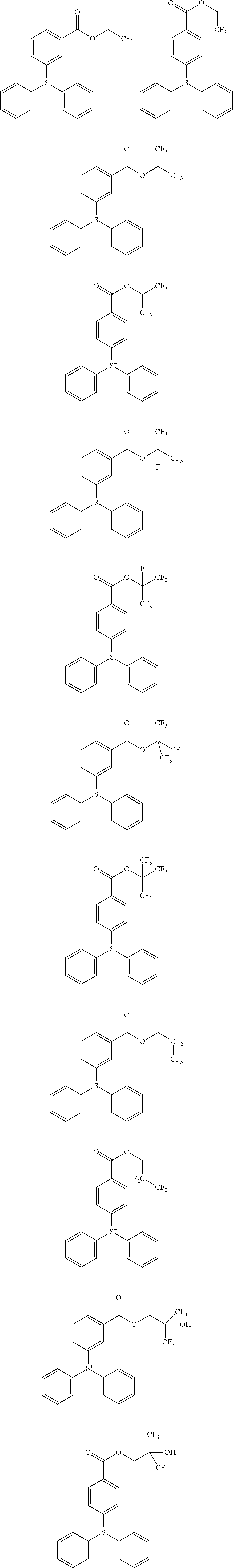

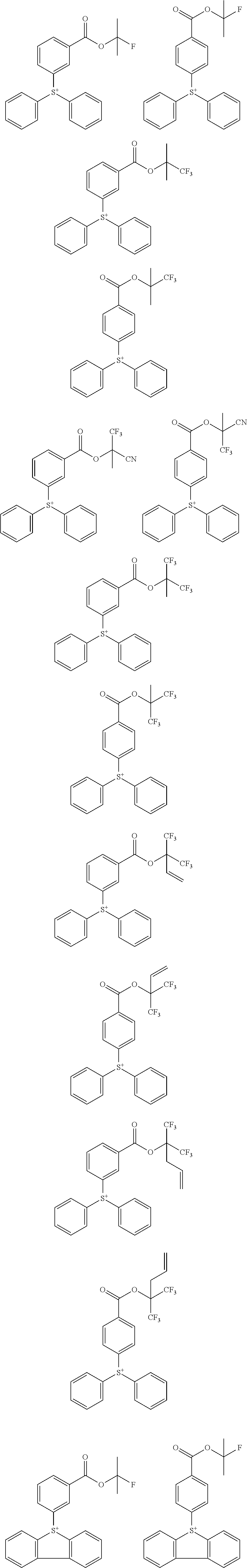

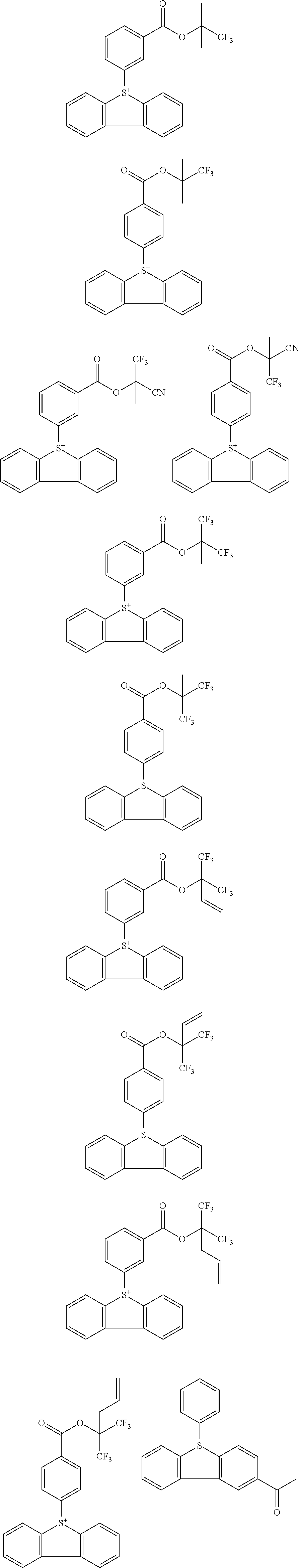

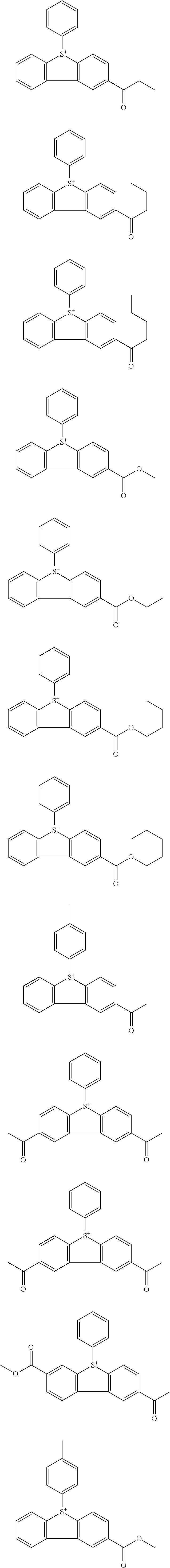

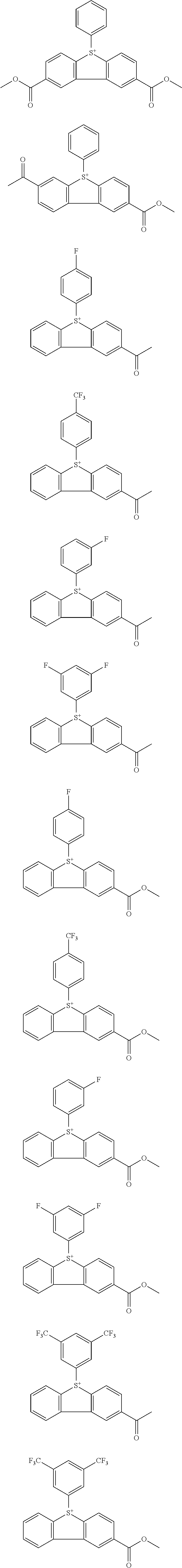

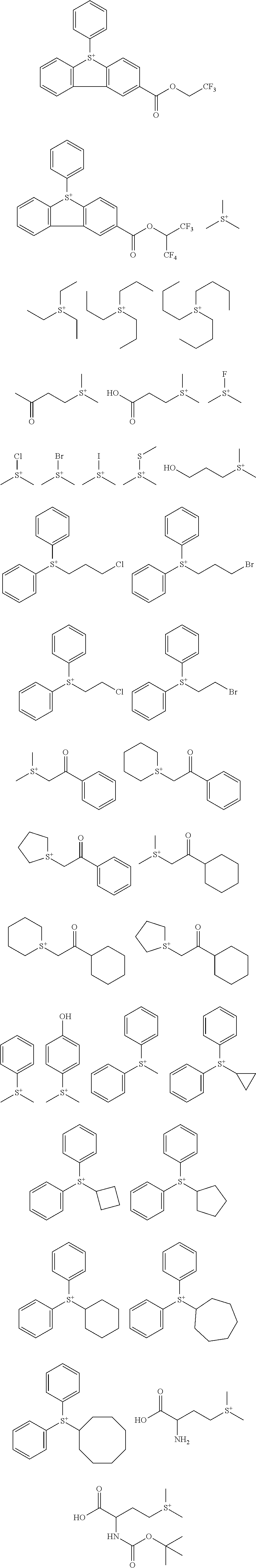

The sulfonium salt having formula (1) can be synthesized, for example, by ion-exchanging a hydrochloride or carbonate having a sulfonium cation with a benzoic acid substituted with a C₂-C₁₄ hydrocarbyloxy group having a trifluoromethyl group.

The sulfonium salt having formula (1) is preferably added to the resist composition of the present invention in an amount of 0.001 to 50 parts by weight, and more preferably 0.01 to 40 parts by weight per 100 parts by weight of the base polymer described later. The sulfonium salt having formula (1) may be used singly or in combination of two or more kinds thereof.

### [Base Polymer]

The resist composition of the present invention may contain a base polymer. When the resist composition is of positive tone, the base polymer contains repeat units containing an acid labile group. The repeat units containing an acid labile group are preferably repeat units having formula (a1) (hereinafter, the repeat units are also referred to as repeat units (a1)) or repeat units having formula (a2) (hereinafter, the repeat units are also referred to as repeat units (a2)).

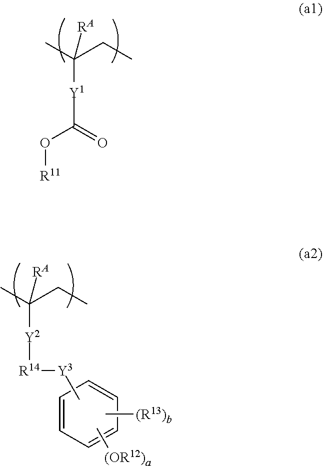

In formulae (a1) and (a2), R^{A} is each independently a hydrogen atom or a methyl group. Y¹ is a single bond, a phenylene group, a naphthylene group, or a C₁-C₁₂ linking group containing at least one moiety selected from an ester bond and a lactone ring. Y² is a single bond or an ester bond. Y³ is a single bond, an ether bond, or an ester bond. R¹¹ and R¹² are each independently an acid labile group. When the base polymer contains both the repeat units (a1) and the repeat units (a2), R¹¹ and R¹² may be identical or different from each other. R¹³ is a fluorine atom, a trifluoromethyl group, a cyano group, or a C₁-C₆ saturated hydrocarbyl group. R¹⁴ is a single bond or a C₁-C₆ alkanediyl group in which some constituent —CH₂— may be substituted with an ether bond or an ester bond. a is 1 or 2, and b is an integer of 0 to 4, provided that 1≤a+b≤5.

Examples of the monomer from which the repeat units (a1) are derived include those shown below, but are not limited thereto. In the formulae, R^{A} and R¹¹ are as defined above.

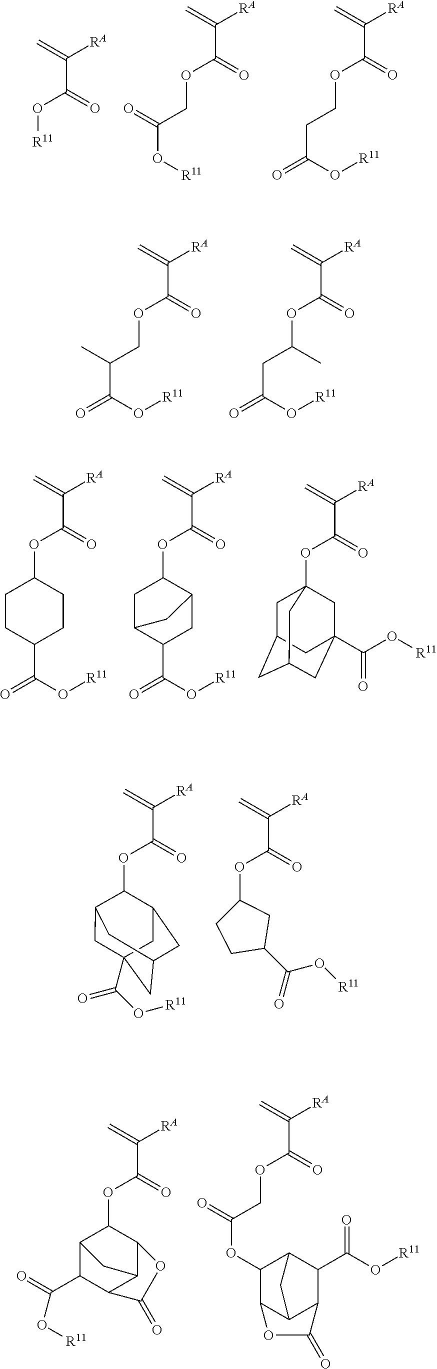

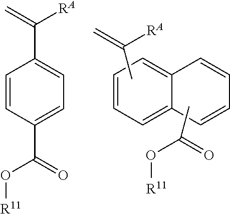

Examples of the monomer from which the repeat units (a2) are derived include those shown below, but are not limited thereto. In the formulae, R^{A} and R¹² are as defined above.

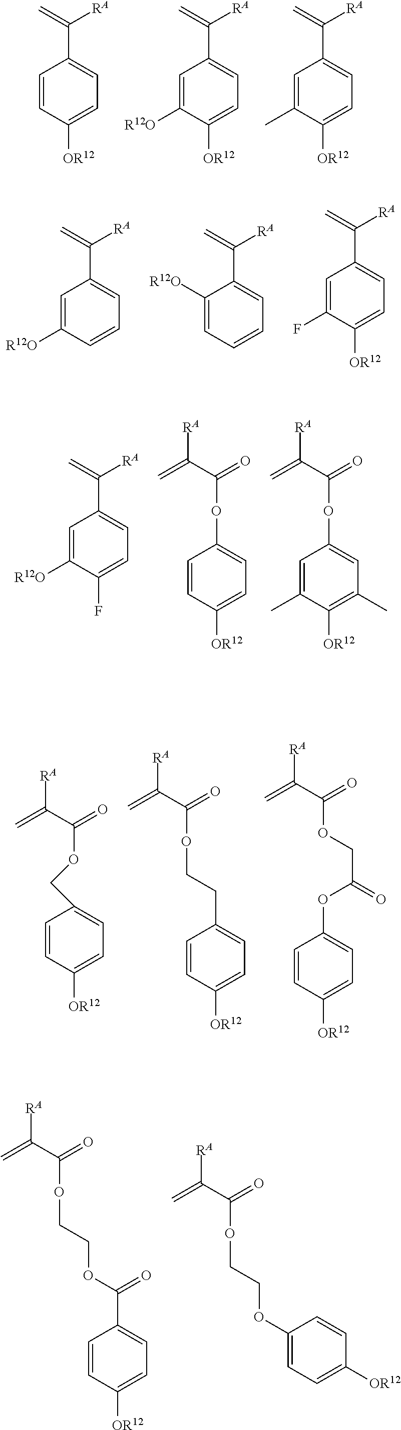

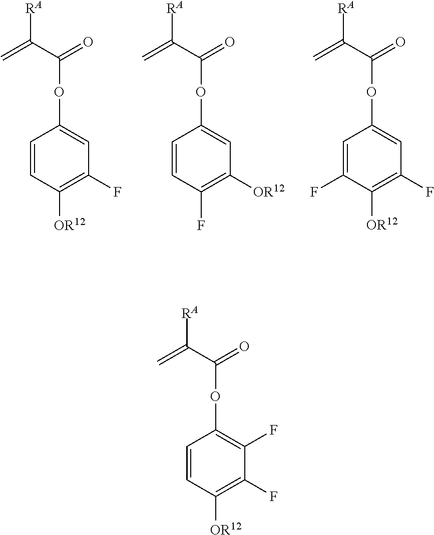

Examples of the acid labile groups represented by R¹¹ and R¹² in formulae (a1) and (a2) include those described in JP-A 2013-080033 and JP-A 2013-083821.

Typical examples of the acid labile groups include those having formulae (AL-1) to (AL-3).

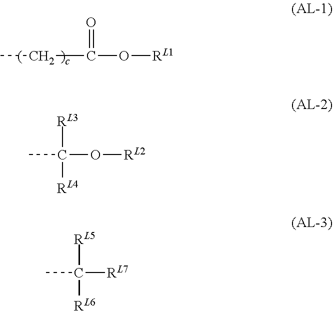

In the formulae, a broken line designates a bond.

In formulae (AL-1) and (AL-2), R^{L1} and R^{L2} are each independently a C₁-C₄₀ hydrocarbyl group which may contain a heteroatom such as an oxygen atom, a sulfur atom, a nitrogen atom, or a fluorine atom. The hydrocarbyl group may be saturated or unsaturated, and may be linear, branched, or cyclic. Preferred are C₁-C₄₀ saturated hydrocarbyl groups, especially C₁-C₂₀ saturated hydrocarbyl groups.

In formula (AL-1), c is an integer of 0 to 10, preferably an integer of 1 to 5.

In formula (AL-2), R^{L3} and R^{L4} are each independently a hydrogen atom or a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be linear, branched, or cyclic. Preferred are C₁-C₂₀ saturated hydrocarbyl groups. Any two of R^{L2}, R^{L3}, and R^{L4} may bond together to form a ring, typically an alicyclic ring, with a carbon atom or carbon and oxygen atoms to which they are bonded, the ring containing 3 to 20 carbon atoms, preferably 4 to 16 carbon atoms.

In formula (AL-3), R^{L5}, R^{L6}, and R^{L7} are each independently a C₁-C₂₀ hydrocarbyl group which may contain a heteroatom such as an oxygen atom, a sulfur atom, a nitrogen atom, or a fluorine atom. The hydrocarbyl group may be saturated or unsaturated, and may be linear, branched, or cyclic. Preferred are C₁-C₂₀ saturated hydrocarbyl groups. Any two of R^{L5}, R^{L6}, and R^{L7} may bond together to form a ring, typically an alicyclic ring, with a carbon atom to which they are bonded, the ring containing 3 to 20 carbon atoms, preferably 4 to 16 carbon atoms.

The base polymer may contain repeat units (b) having a phenolic hydroxy group as an adhesive group. Examples of the monomer from which the repeat units (b) are derived include those shown below, but are not limited thereto. In the formulae, R^{A} is as defined above.

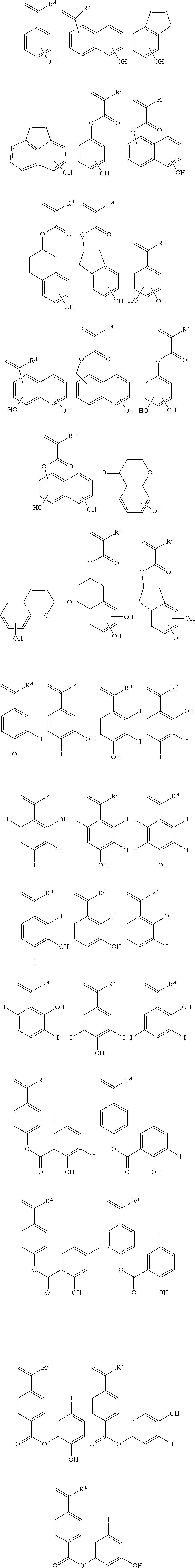

The base polymer may contain repeat units (c) having another adhesive group selected from a hydroxy group other than the phenolic hydroxy group, a lactone ring, a sultone ring, an ether bond, an ester bond, a sulfonic ester bond, a carbonyl group, a sulfonyl group, a cyano group, and a carboxy group. Examples of the monomer from which the repeat units (c) are derived include those shown below, but are not limited thereto. In the formulae, R^{A} is as defined above.

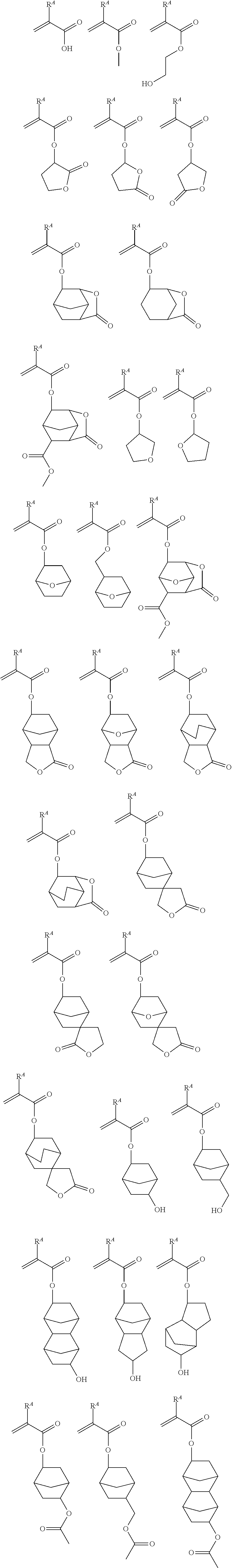

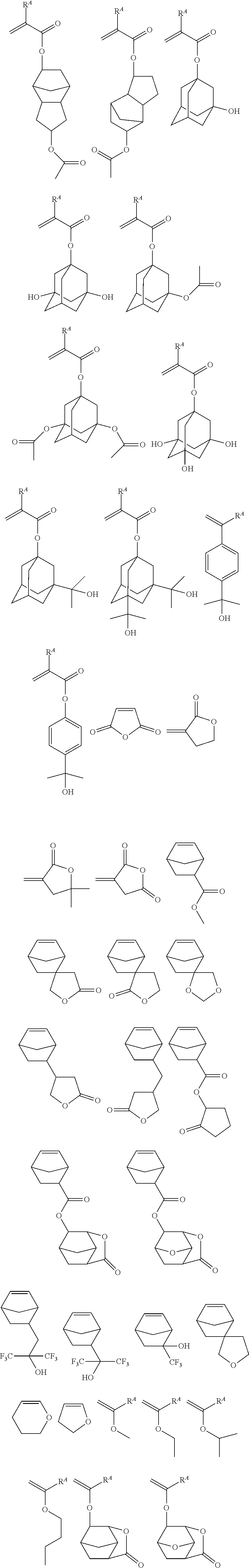

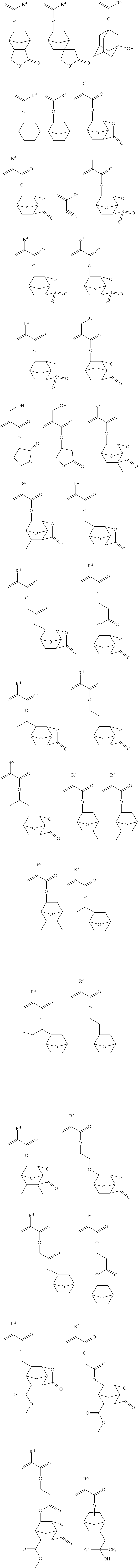

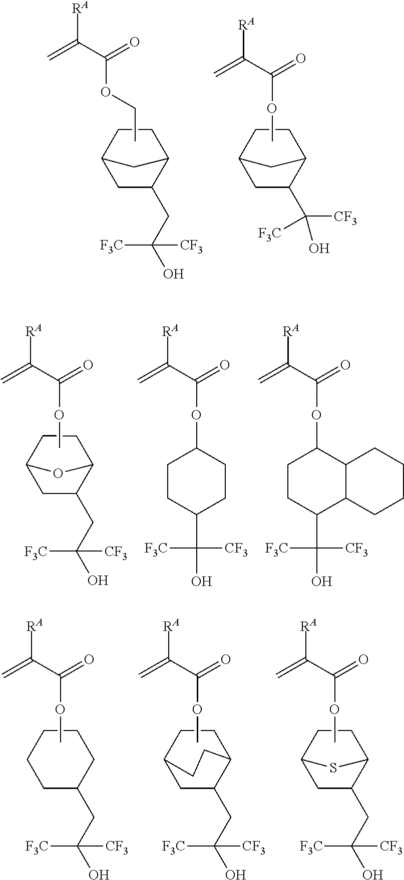

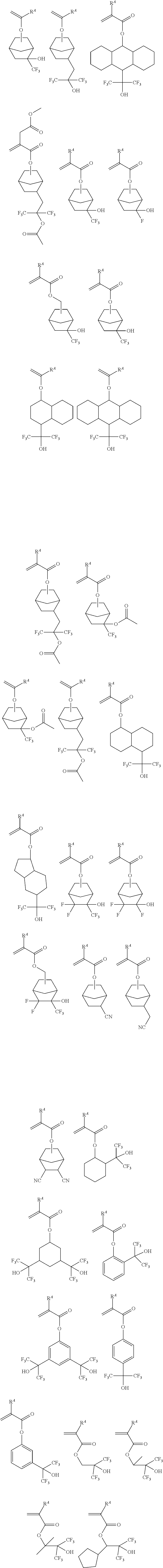

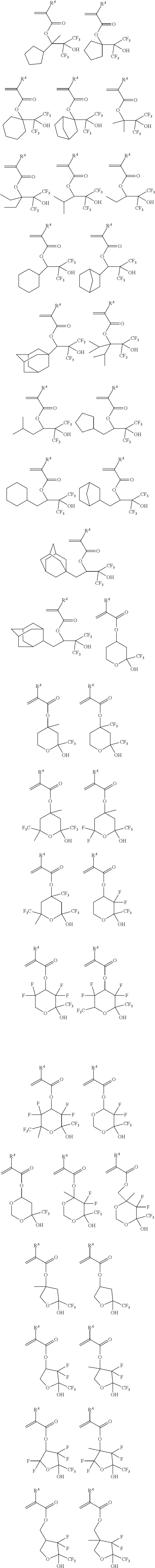

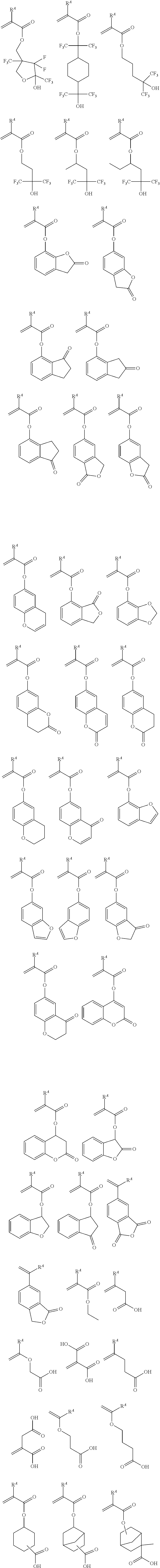

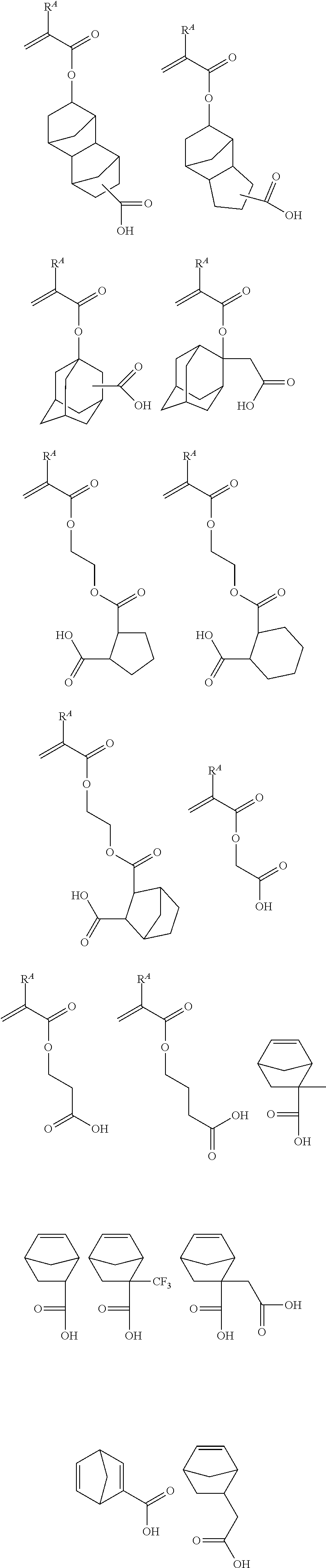

The base polymer may contain repeat units (d) derived from indene, benzofuran, benzothiophene, acenaphthylene, chromone, coumarin, norbornadiene, or a derivative thereof. Examples of the monomer from which the repeat units (d) are derived include those shown below, but are not limited thereto.

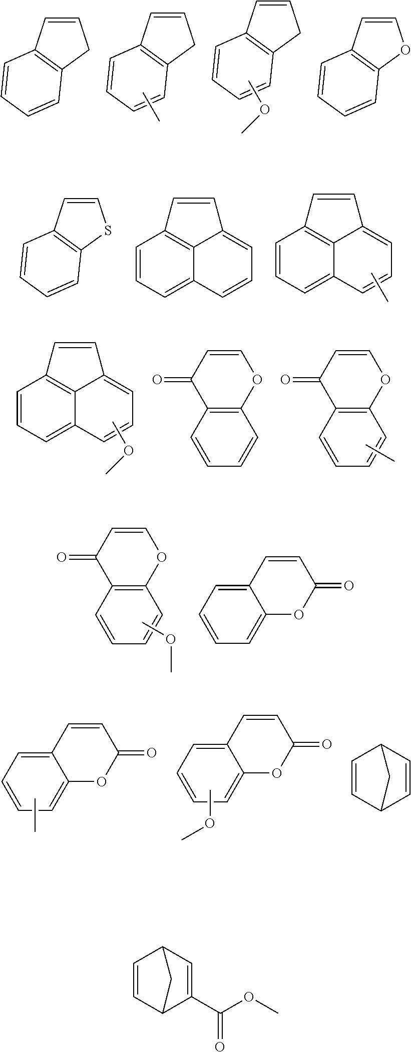

The base polymer may contain repeat units (e) derived from styrene, vinylnaphthalene, vinylanthracene, vinylpyrene, methyleneindane, vinylpyridine, or vinylcarbazole.

The base polymer may contain repeat units (f) derived from an onium salt containing a polymerizable unsaturated bond. Examples of the preferred repeat units (f) include repeat units having formula (f1) (hereinafter, the repeat units are also referred to as repeat units (f1)), repeat units having formula (f2) (hereinafter, the repeat units are also referred to as repeat units (f2)), and repeat units having formula (f3) (hereinafter, the repeat units are also referred to as repeat units (f3)). The repeat units (f1) to (f3) may each be used singly or in combination of two or more kinds thereof.

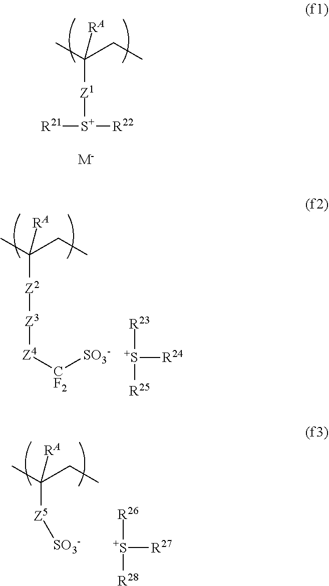

In formulae (f1) to (f3), R^{A} is each independently a hydrogen atom or a methyl group. Z¹ is a single bond, a C₁-C₆ aliphatic hydrocarbylene group, a phenylene group, a naphthylene group, a C₇-C₁₈ group obtained by combining the foregoing, —O—Z¹¹—, —C(═O)—O—Z¹¹—, or —C(═O)—NH—Z¹¹—. Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group. Z² is a single bond or an ester bond. Z³ is a single bond, —Z³¹—C(═O)—O—, —Z³¹—O—, or —Z³¹—O—C(═O)—. Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom. Z⁴ is a methylene group, a 2,2,2-trifluoro-1,1-ethanediyl group, or a carbonyl group. Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—. Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a halogen atom, or a hydroxy group.

In formulae (f1) to (f3), R²¹ to R²⁸ are each independently a halogen atom or a C₁-C₂₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R⁴ to R⁶ in the description of formula (1). Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. R²³ and R²⁴ or R²⁶ and R²⁷ may bond together to form a ring with a sulfur atom to which they are bonded. Examples of the ring include those rings mentioned as the ring formed by the bond of R⁴ and R⁵ with a sulfur atom to which they are bonded in the description of formula (1).

In formula (f1), M⁻ is a non-nucleophilic counter ion. Examples of the non-nucleophilic counter ion include halide ions such as a chloride ion and a bromide ion; fluoroalkylsulfonate ions such as a triflate ion, a 1,1,1-trifluoroethanesulfonate ion, and a nonafluorobutanesulfonate ion; arylsulfonate ions such as a tosylate ion, a benzenesulfonate ion, a 4-fluorobenzenesulfonate ion, and a 1,2,3,4,5-pentafluorobenzenesulfonate ion; alkylsulfonate ions such as a mesylate ion and a butanesulfonate ion; imide ions such as a bis(trifluoromethylsulfonyl)imide ion, a bis(perfluoroethylsulfonyl)imide ion, and a bis(perfluorobutylsulfonyl)imide ion; and methide ions such as a tris(trifluoromethylsulfonyl)methide ion and a tris(perfluoroethylsulfonyl)methide ion.

Other examples of the non-nucleophilic counter ion include sulfonate ions having a fluorine atom substituted at the α-position as represented by formula (f1-1) and sulfonate ions having a fluorine atom substituted at the α-position and a trifluoromethyl group substituted at the β-position as represented by formula (f1-2).

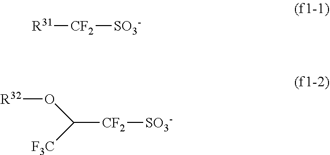

In formula (f1-1), R³¹ is a hydrogen atom or a C₁-C₂₀ hydrocarbyl group which may contain an ether bond, an ester bond, a carbonyl group, a lactone ring, or a fluorine atom. The hydrocarbyl group may be saturated or unsaturated, and may be linear, branched, or cyclic. Specific examples thereof include those groups mentioned as the hydrocarbyl group represented by R^{fa1} in formula (2A′) described later.

In formula (f1-2), R³² is a hydrogen atom, a C₁-C₃₀ hydrocarbyl group, or a C₂-C₃₀ hydrocarbylcarbonyl group, and the hydrocarbyl group and the hydrocarbylcarbonyl group may contain an ether bond, an ester bond, a carbonyl group, or a lactone ring. The hydrocarbyl group and the hydrocarbyl moiety in the hydrocarbylcarbonyl group may be saturated or unsaturated, and may be linear, branched, or cyclic. Specific examples thereof include those groups mentioned as the hydrocarbyl group represented by R^{fa1} in formula (2A′) described later.

Examples of the cation in the monomer from which the repeat units (f1) are derived include those shown below, but are not limited thereto. In the formulae, R^{A} is as defined above.

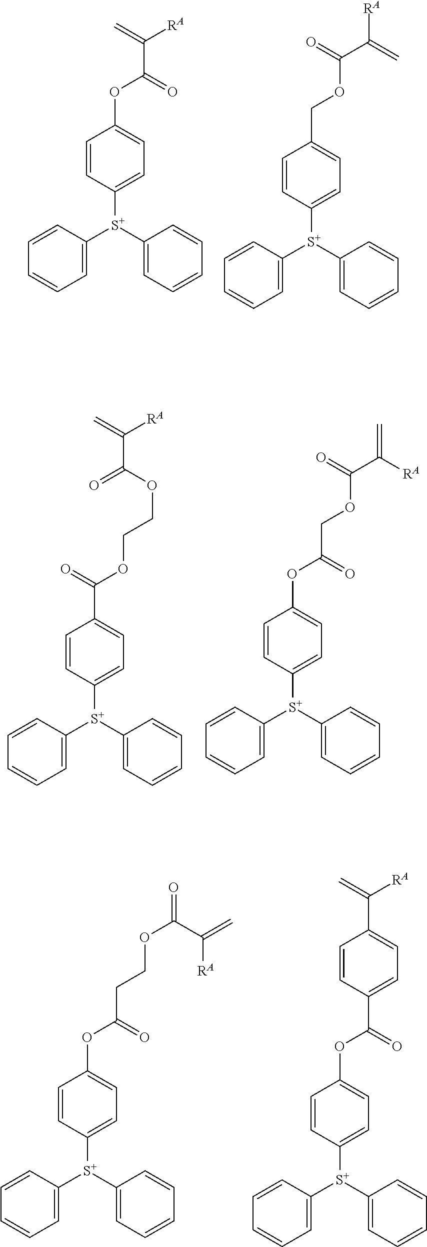

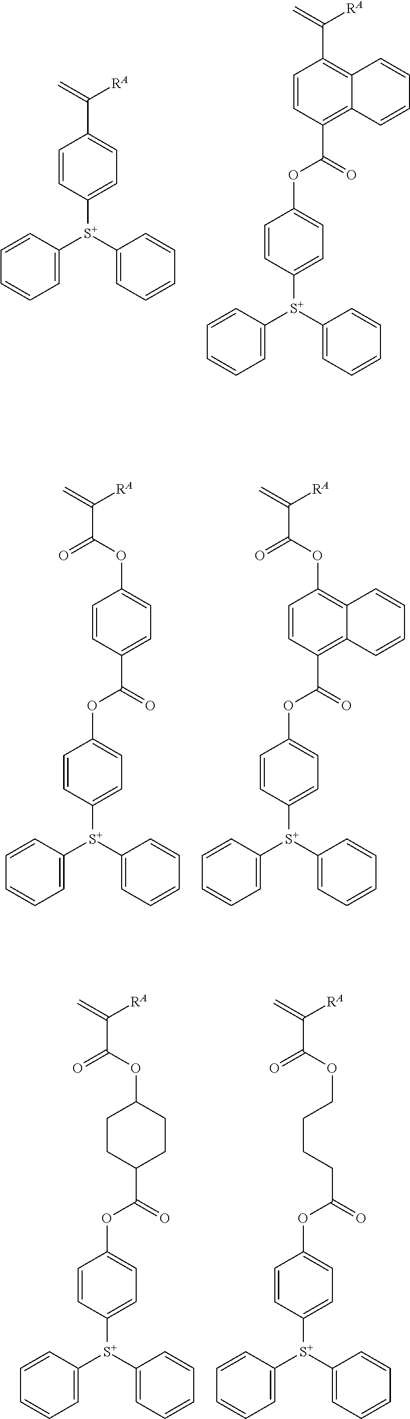

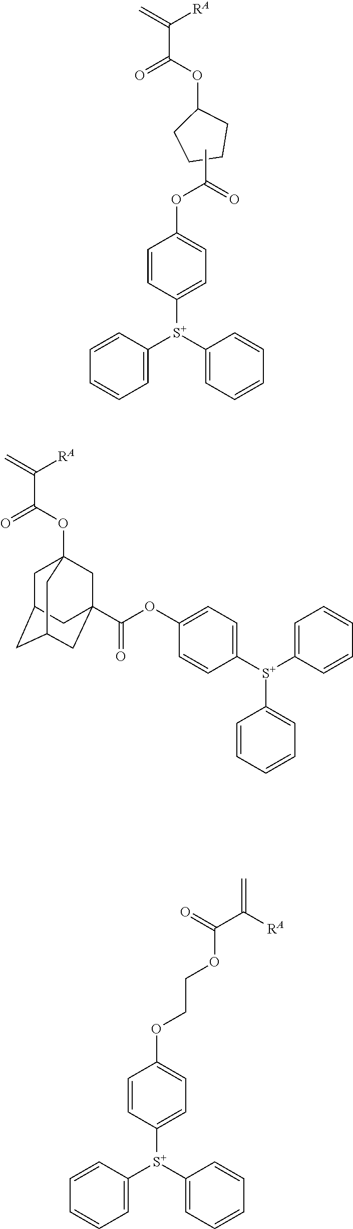

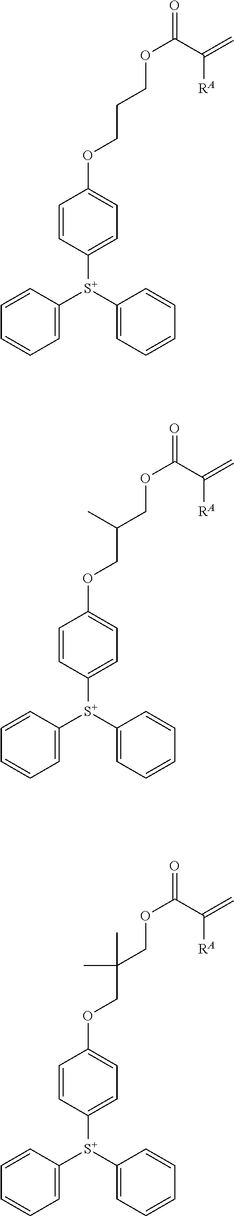

Specific examples of the cation in the monomer from which the repeat units (C) or (f3) are derived include those cations mentioned as the cation of the sulfonium salt having formula (1).

Examples of the anion in the monomer from which the repeat units (f2) are derived include those shown below, but are not limited thereto. In the formulae, R^{A} is as defined above.

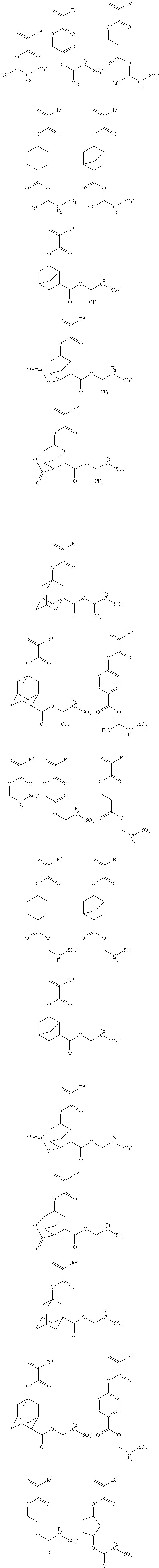

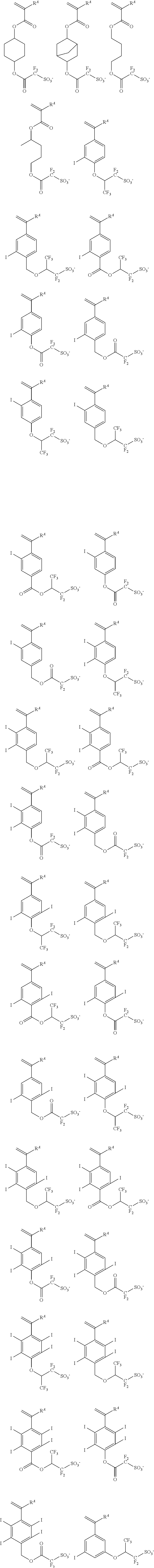

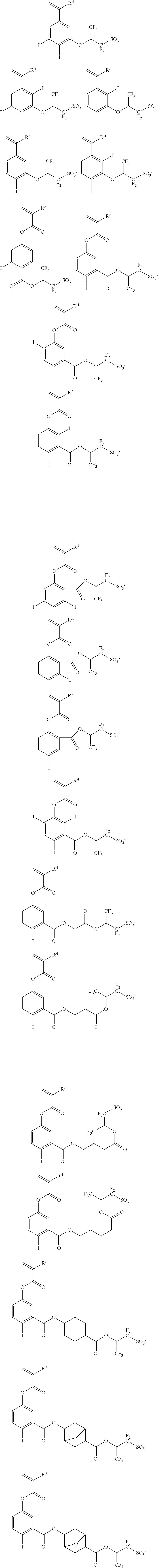

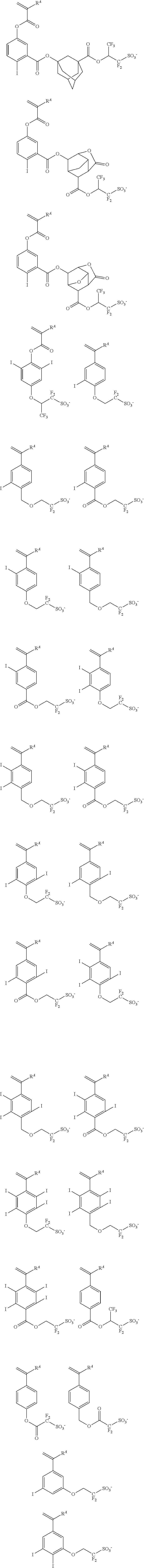

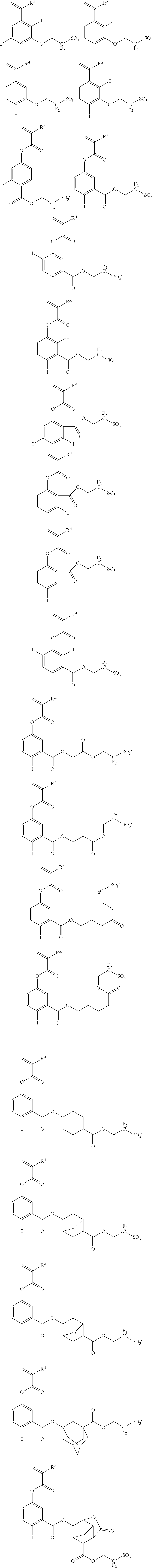

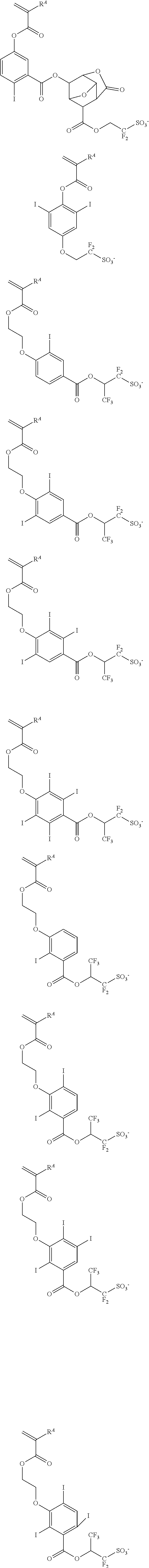

Examples of the anion in the monomer from which the repeat units (f) are derived include those shown below, but are not limited thereto. In the formulae, R^{A} is as defined above.

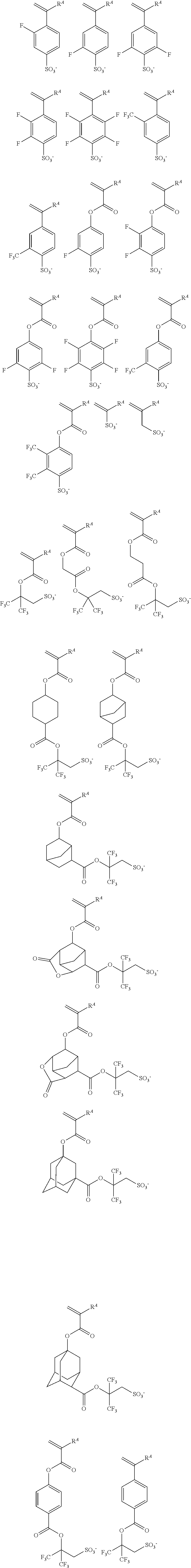

The repeat units (f1) to (f3) have a function of an acid generator. Bonding an acid generator to the polymer backbone is effective in reducing acid diffusion, thereby preventing a reduction of resolution due to blur by acid diffusion. In addition, the LWR and CDU are improved since the acid generator is uniformly distributed. Use of a base polymer containing the repeat units (f) may avoid the necessity for an acid generator of addition type described later.

In the base polymer, the fractions of the repeat units (a1), (a2), (b), (c), (d), (e), (f1), (f2), and (f3) are preferably 0≤(a1)≤0.9, 0≤(a2)≤0.9, 0≤(a1)+(a2)≤0.9, 0≤(b)≤0.9, 0≤(c)≤0.9, 0≤(d)≤0.5, 0≤(e)≤0.5, 0≤(f1)≤0.5, 0≤(f2)≤0.5, 0≤(f3)≤0.5, and 0≤(f1)+(f2)+(f3)≤0.5, more preferably 0 $ (a1)≤0.8, 0≤(a2)≤0.8, 0≤(a1)+(a2)≤0.8, 0≤(b)≤0.8, 0≤(c)≤0.8, 0≤(d)≤0.4, 0≤(e)≤0.4, 0≤(f1)≤0.4, 0≤(f2)≤0.4, 0≤(f3)≤0.4, and 0≤(f1)+(f2)+(f3)≤0.4, and even more preferably 0≤(a1)≤0.7, 0≤(a2)≤0.7, 0≤(a1)+(a2)≤0.7, 0≤(b)≤0.7, 0≤(c)≤0.7, 0≤(d)≤0.3, 0≤(e)≤0.3, 0≤(f1)≤0.3, 0≤(f2)≤0.3, 0≤(f3)≤0.3, and 0≤(f1)+(f2)+(f3)≤0.3. Note that (a1)+(a2)+(b)+(c)+(d)+(f1)+(f2)+(f3)+(e)=1.0.

The base polymer may be synthesized, for example, by heating a monomer from which the repeat units are derived in an organic solvent with the addition of a radical polymerization initiator to perform polymerization.

Examples of the organic solvent used in the polymerization include toluene, benzene, tetrahydrofuran (THF), diethyl ether, and dioxane. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, and lauroyl peroxide. The temperature during polymerization is preferably 50 to 80° C. The reaction time is preferably 2 to 100 hours, and more preferably 5 to 20 hours.

When a monomer having a hydroxy group is copolymerized, the hydroxy group may be substituted with an acetal group susceptible to deprotection with an acid such as an ethoxyethoxy group prior to polymerization, and the polymerization be followed by deprotection with a weak acid and water. Alternatively, the hydroxy group may be substituted with an acetyl group, a formyl group, a pivaloyl group or the like prior to polymerization, and the polymerization be followed by alkaline hydrolysis.

When hydroxystyrene or hydroxyvinylnaphthalene is copolymerized, acetoxystyrene or acetoxyvinylnaphthalene may be used instead of hydroxystyrene or hydroxyvinylnaphthalene, and after polymerization, the acetoxy group may be deprotected by alkaline hydrolysis for converting the polymer product to hydroxystyrene or hydroxyvinylnaphthalene.

For alkaline hydrolysis, a base such as aqueous ammonia or triethylamine may be used. The reaction temperature is preferably −20 to 100° C., and more preferably 0 to 60° C. The reaction time is preferably 0.2 to 100 hours, and more preferably 0.5 to 20 hours.

The base polymer preferably has a weight average molecular weight (Mw) in the range of 1,000 to 500,000, and more preferably 2,000 to 30,000, as measured by gel permeation chromatography (GPC) versus polystyrene standards using a THF solvent. A Mw in the range ensures that the resist film has heat resistance and high solubility in an alkaline developer.

If the base polymer has a wide molecular weight distribution (Mw/Mn), which indicates the presence of lower and higher molecular weight polymer fractions, there is a possibility that foreign matters are left on the pattern or the pattern profile is degraded after exposure. The influences of Mw and Mw/Mn tend to be stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

The base polymer may contain two or more polymers having different compositional ratios, Mw, and Mw/Mn.

### [Acid Generator]

The resist composition of the present invention may contain an acid generator that generates a strong acid (hereinafter, the acid generator is also referred to as acid generator of addition type). The strong acid as used herein means, in the case of a chemically amplified positive resist composition, a compound having an acidity sufficient to cause a deprotection reaction of an acid labile group of a base polymer, and means, in the case of a chemically amplified negative resist composition, a compound having an acidity sufficient to cause a polarity switch reaction or a crosslinking reaction by an acid. When the resist composition contains such an acid generator, the sulfonium salt having formula (1) described above functions as a quencher, and the resist composition of the present invention can function as a chemically amplified positive resist composition or a chemically amplified negative resist composition.

Examples of the acid generator include a compound that generates an acid in response to actinic rays or radiation (the compound is referred to as photoacid generator). Although the photoacid generator may be any compound capable of generating an acid upon exposure to high-energy radiation, those compounds capable of generating a sulfonic acid, an imide acid (imidic acid), or a methide acid are preferred. Suitable photoacid generators include sulfonium salts, iodonium salts, sulfonyldiazomethane, N-sulfonyloxyimide, and oxime-O-sulfonate acid generators. Specific examples of the photoacid generator include those described in paragraphs [0122] to [0142] of JP-A 2008-111103.

In addition, as the photoacid generator, a sulfonium salt having formula (2-1) and an iodonium salt having formula (2-2) can also be suitably used.

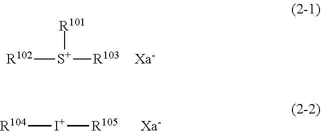

In formulae (2-1) and (2-2), R¹⁰¹ to R¹⁰⁵ are each independently a halogen atom or a C₁-C₂₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R⁴ to R⁶ in the description of formula (1). R¹⁰¹ and R¹⁰² may bond together to form a ring with a sulfur atom to which they are bonded. Examples of the ring include those rings mentioned as the ring formed by the bond of R⁴ and R⁵ with a sulfur atom to which they are bonded in the description of formula (1).

Examples of a cation of the sulfonium salt having formula (2-1) include those cations mentioned as the cation of the sulfonium salt having formula (1).

Examples of a cation of the iodonium salt having formula (2-2) include those shown below, but are not limited thereto.

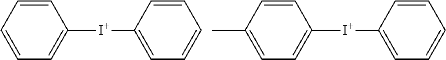

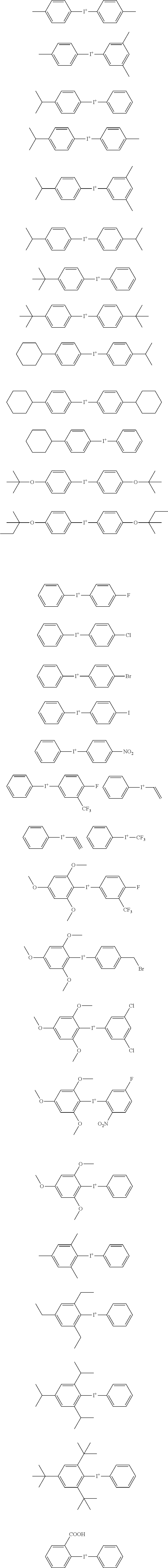

In formulae (2-1) and (2-2), Xa⁻ represents an anion selected from formulae (2A) to (2D).

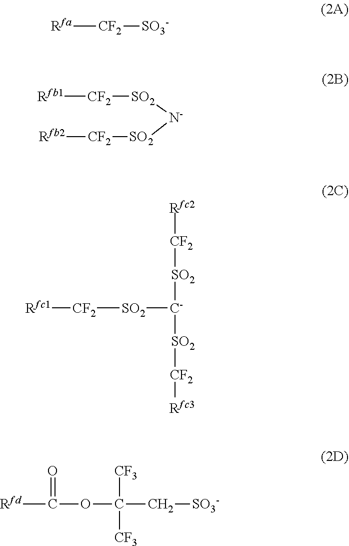

In formula (2A), R^{fa} is a fluorine atom or a C₁-C₄₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa} in formula (2A′) described later.

The anion having formula (2A) is preferably an anion having formula (2A′).

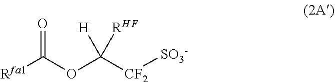

In formula (2A′), R^{HF} is a hydrogen atom or a trifluoromethyl group, and is preferably a trifluoromethyl group. R^{fa} is a C₁-C₃₈ hydrocarbyl group which may contain a heteroatom. The heteroatom is preferably an oxygen atom, a nitrogen atom, a sulfur atom, a halogen atom, or the like, and more preferably an oxygen atom. The hydrocarbyl group is particularly preferably a C₆-C₃₀ hydrocarbyl group from the viewpoint of obtaining high resolution in fine pattern formation.

The hydrocarbyl group represented by R^{fa1} may be saturated or unsaturated, and may be linear, branched, or cyclic. Specific examples thereof include C₁-C₃₈ alkyl groups such as a methyl group, an ethyl group, a n-propyl group, an isopropyl group, a n-butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosyl group; C₃-C₃₈ cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group; C₂-C₃₈ unsaturated aliphatic hydrocarbyl groups such as an allyl group and a 3-cyclohexenyl group; C₆-C₃₈ aryl groups such as a phenyl group, a 1-naphthyl group, and a 2-naphthyl group; C₇-C₃₈ aralkyl groups such as a benzyl group and a diphenylmethyl group; and groups obtained by combining the foregoing.

Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Examples of the heteroatom-containing hydrocarbyl group include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

Synthesis of a sulfonium salt containing the anion having formula (2A′) is described in detail in, for example, JP-A 2007-145797, JP-A 2008-106045, JP-A 2009-007327, and JP-A 2009-258695. In addition, sulfonium salts described in, for example, JP-A 2010-215608, JP-A 2012-041320, JP-A 2012-106986, and JP-A 2012-153644 are also suitably used.

Examples of the anion having formula (2A) include those mentioned as the anion having formula (1A) in JP-A 2018-197853.

In formula (2B), R^{fb1} and R^{fb2} are each independently a fluorine atom or a C₁-C₄₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (2A′). Each of R^{fb1} and R^{fb2} is preferably a fluorine atom or a C₁-C₄ linear fluorinated alkyl group. R^{fb1} and R^{fb2} may bond together to form a ring with a group to which they are bonded, that is, the group —CF₂—SO₂—N—SO₂—CF₂—, and in this case, the group obtained by bonding of R^{fb1} and R^{fb2} together is preferably a fluorinated ethylene group or a fluorinated propylene group.

In formula (2C), R^{fc1}, R^{fc2}, and R^{fc3} are each independently a fluorine atom or a C₁-C₄₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (2A′). Each of R^{fc1}, R^{fc2}, and R^{fc3} is preferably a fluorine atom or a C₁-C₄ linear fluorinated alkyl group. R^{fc1} and R^{fc2} may bond together to form a ring with a group to which they are bonded, that is, the group —CF₂—SO₂—C—SO₂—CF₂—, and in this case, the group obtained by bonding of R^{fc1} and R^{fc2} together is preferably a fluorinated ethylene group or a fluorinated propylene group.

In formula (2D), R^{fd} is a C₁-C₄₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (2A′).

Synthesis of a sulfonium salt containing the anion having formula (2D) is described in detail in, for example, JP-A 2010-215608 and JP-A 2014-133723.

Examples of the anion having formula (2D) include those mentioned as the anion having formula (1D) in JP-A 2018-197853.

The photoacid generator containing the anion having formula (2D) does not have a fluorine atom at the α-position of the sulfo group, but has two trifluoromethyl groups at the β-position, and thus has an acidity sufficient for cleaving the acid labile group in the base polymer. Therefore, the compound can be used as a photoacid generator.

As the photoacid generator, one having formula (3) can also be suitably used.

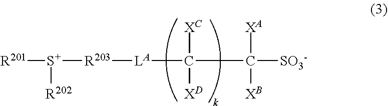

In formula (3), R²⁰¹ and R²⁰² are each independently a halogen atom or a C₁-C₃₀ hydrocarbyl group which may contain a heteroatom. R²⁰³ is a C₁-C₃₀ hydrocarbylene group which may contain a heteroatom. Any two of R²⁰¹, R²⁰², and R²⁰³ may bond together to form a ring with a sulfur atom to which they are bonded. Examples of the ring include those rings mentioned as the ring formed by the bond of R⁴ and R⁵ with a sulfur atom to which they are bonded in the description of formula (1).

The hydrocarbyl group represented by R²⁰¹ and R²⁰² may be saturated or unsaturated, and may be linear, branched, or cyclic. Specific examples thereof include C₁-C₃₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₃₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, an oxanorbornyl group, a tricyclo[5.2.1.0^{2,6}]decanyl group, and an adamantyl group; C₆-C₃₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, a tert-butylnaphthyl group, and an anthracenyl group; and groups obtained by combining the foregoing. Some or all of hydrogen atoms of the hydrocarbyl group may be substituted with a group containing a heteroatom such as an oxygen atom, a sulfur atom, a nitrogen atom, or a halogen atom, and some of —CH₂— of the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group.

The hydrocarbylene group represented by R²⁰³ may be saturated or unsaturated, and may be linear, branched, or cyclic. Specific examples thereof include C₁-C₃₀ alkanediyl groups such as a methanediyl group, an ethane-1,1-diyl group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; C₃-C₃₀ cyclic saturated hydrocarbylene groups such as a cyclopentanediyl group, a cyclohexanediyl group, a norbornanediyl group, and an adamantanediyl group; C₆-C₃₀ arylene groups such as a phenylene group, a methylphenylene group, an ethylphenylene group, a n-propylphenylene group, an isopropylphenylene group, a n-butylphenylene group, an isobutylphenylene group, a sec-butylphenylene group, a tert-butylphenylene group, a naphthylene group, a methylnaphthylene group, an ethylnaphthylene group, a n-propylnaphthylene group, an isopropylnaphthylene group, a n-butylnaphthylene group, an isobutylnaphthylene group, a sec-butylnaphthylene group, and a tert-butylnaphthylene group; and groups obtained by combining the foregoing. Some or all of hydrogen atoms of the hydrocarbylene group may be substituted with a group containing a heteroatom such as an oxygen atom, a sulfur atom, a nitrogen atom, or a halogen atom, and some of —CH₂— of the hydrocarbylene group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. The heteroatom is preferably an oxygen atom.

In formula (3), L^{A} is a single bond, an ether bond, or a C₁-C₂₀ hydrocarbylene group which may contain a heteroatom. The hydrocarbylene group may be saturated or unsaturated, and may be linear, branched, or cyclic. Specific examples thereof include those groups mentioned as the hydrocarbylene group represented by R²⁰³

In formula (3), X^{A}, X^{B}, X^{C}, and X^{D} are each independently a hydrogen atom, a fluorine atom, or a trifluoromethyl group. However, at least one of X^{A}, X^{B}, X^{C}, and X^{D} is a fluorine atom or a trifluoromethyl group.

In formula (3), k is an integer of 0 to 3.

The photoacid generator having formula (3) is preferably a photoacid generator having formula (3′).

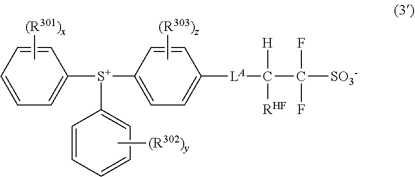

In formula (3′), L^{A} is as defined above. R^{HF} is a hydrogen atom or a trifluoromethyl group, and is preferably a trifluoromethyl group. R³⁰¹, R³⁰², and R³⁰³ are each independently a hydrogen atom or a C₁-C₂₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R^{fa1} in formula (2A′). x and y are each independently an integer of 0 to 5, and z is an integer of 0 to 4.

Examples of the photoacid generator having formula (3) include those mentioned as the photoacid generator having formula (2) in JP-A 2017-026980.

Among the photoacid generators, those containing the anion having formula (2A′) or (2D) are particularly preferred because they are reduced in acid diffusion and have excellent solubility in solvents. In addition, those having formula (3′) are particularly preferred because they are highly reduced in acid diffusion.

As the photoacid generator, a sulfonium salt or an iodonium salt containing an anion having an aromatic ring substituted with an iodine atom or a bromine atom can also be used. Examples of such a salt include those having formula (4-1) or (4-2).

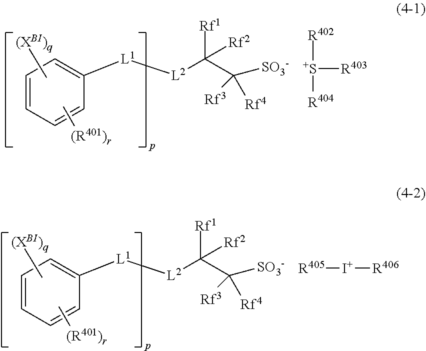

In formulae (4-1) and (4-2), p is an integer satisfying 1≤p≤3. q and r are integers satisfying 1≤q≤5, 0≤r≤3, and 1≤q+r≤5. q is preferably an integer satisfying 1≤q≤3, and more preferably 2 or 3. r is preferably an integer satisfying 0≤r≤2.

In formulae (4-1) and (4-2), X^{BI} is an iodine atom or a bromine atom, and groups X^{BI} may be identical or different from each other when p and/or q is 2 or more.

In formulae (4-1) and (4-2), L¹ is a single bond, an ether bond, an ester bond, or a C₁-C₆ saturated hydrocarbylene group which may contain an ether bond or an ester bond. The saturated hydrocarbylene group may be linear, branched, or cyclic.

In formulae (4-1) and (4-2), L² is a single bond or a C₁-C₂₀ divalent linking group when p is 1, and a C₁-C₂₀ (p+1)-valent linking group which may contain an oxygen atom, a sulfur atom, or a nitrogen atom when p is 2 or 3.

In formulae (4-1) and (4-2), R⁴⁰¹ is a hydroxy group, a carboxy group, a fluorine atom, a chlorine atom, a bromine atom, an amino group, or a C₁-C₂₀ hydrocarbyl group, a C₁-C₂₀ hydrocarbyloxy group, a C₂-C₂₀ hydrocarbylcarbonyl group, a C₂-C₂₀ hydrocarbyloxycarbonyl group, a C₂-C₂₀ hydrocarbylcarbonyloxy group, or a C₁-C₂₀ hydrocarbylsulfonyloxy group, which may contain a fluorine atom, a chlorine atom, a bromine atom, a hydroxy group, an amino group, or an ether bond, or —N(R^{401A})(R^{401B}), —N(R^{401C})—C(═O)—R^{401D} or —N(R^{401C})—C(═O)—O—R^{401D}. R^{401A} and R^{401B} are each independently a hydrogen atom or a C₁-C₆ saturated hydrocarbyl group. R^{401C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{401D} is a C₁-C₁₆ aliphatic hydrocarbyl group, a C₆-C₁₄ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated, and may be linear, branched, or cyclic. The hydrocarbyl group, the hydrocarbyloxy group, the hydrocarbyloxycarbonyl group, the hydrocarbylcarbonyl group, the hydrocarbylcarbonyloxy group, and the hydrocarbylsulfonyloxy group may be linear, branched, or cyclic. Groups R⁴⁰¹ may be identical or different when p and/or r is 2 or more.

Among them, R⁴⁰¹ is preferably a hydroxy group, —N(R^{401C})—C(═O)—R^{401D}, —N(R^{401C})—C(═O)—O—R^{401D}, a fluorine atom, a chlorine atom, a bromine atom, a methyl group, a methoxy group, or the like.

In formulae (4-1) and (4-2), Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may together form a carbonyl group. It is particularly preferred that both Rf³ and Rf⁴ are fluorine atoms.

In formulae (4-1) and (4-2), R⁴⁰² to R⁴⁰⁶ are each independently a halogen atom or a C₁-C₂₀ hydrocarbyl group which may contain a heteroatom. The hydrocarbyl group may be saturated or unsaturated, and may be linear, branched, or cyclic. Specific examples thereof include those groups mentioned as the hydrocarbyl group represented by R⁴ to R⁶ in the description of formula (1). Some or all of hydrogen atoms of the hydrocarbyl group may be substituted with a hydroxy group, a carboxy group, a halogen atom, a cyano group, a nitro group, a mercapto group, a sultone ring, a sulfo group, or a sulfonium salt-containing group, and some of —CH₂— of the hydrocarbyl group may be substituted with an ether bond, an ester bond, a carbonyl group, an amide bond, a carbonate bond, or a sulfonic ester bond. R⁴⁰² and R⁴⁰³ may bond together to form a ring with a sulfur atom to which they are bonded. Examples of the ring include those rings mentioned as the ring formed by the bond of R⁴ and R⁵ with a sulfur atom to which they are bonded in the description of formula (1).

Examples of a cation of the sulfonium salt having formula (4-1) include those cations mentioned as the cation of the sulfonium salt having formula (1). In addition, examples of a cation of the iodonium salt having formula (4-2) include those cations mentioned as the cation of the iodonium salt having formula (2-2).

Examples of an anion of the onium salt having formula (4-1) or (4-2) include those shown below, but are not limited thereto. In the formulae, X^{BI} is as defined above.

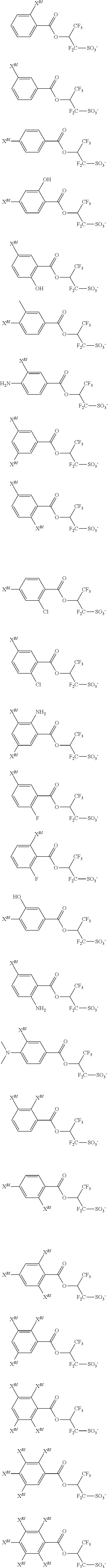

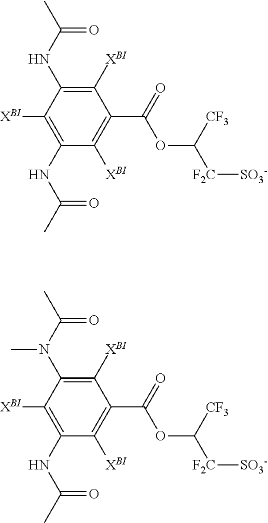

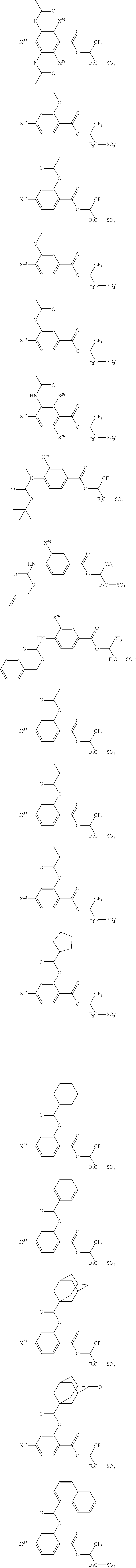

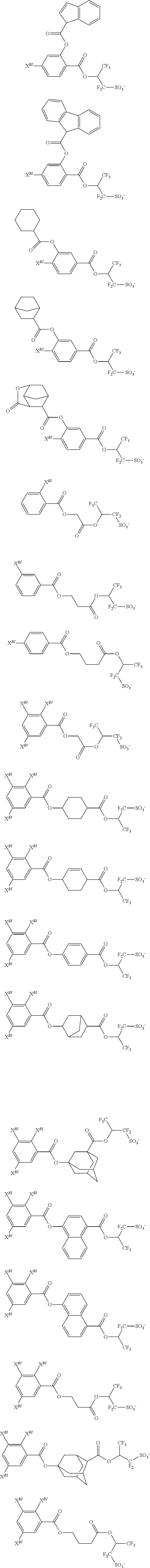

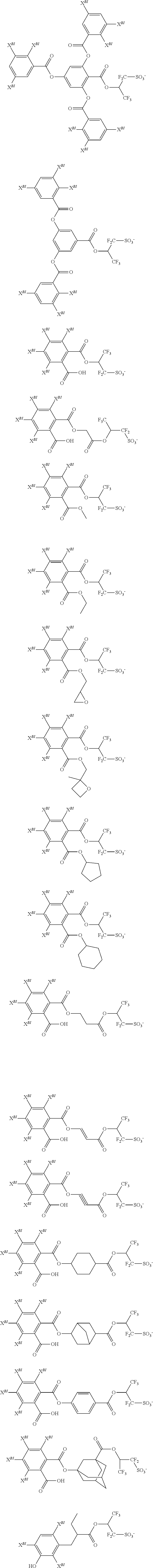

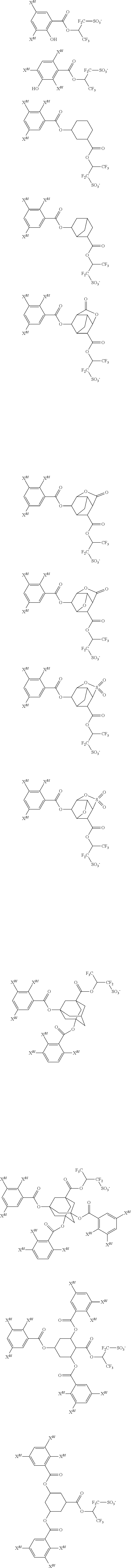

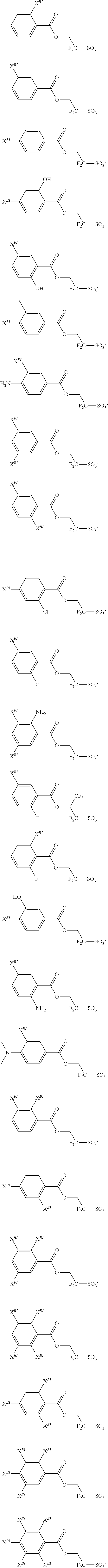

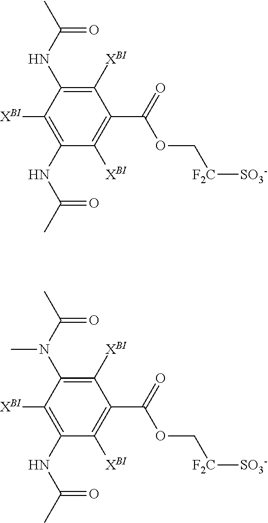

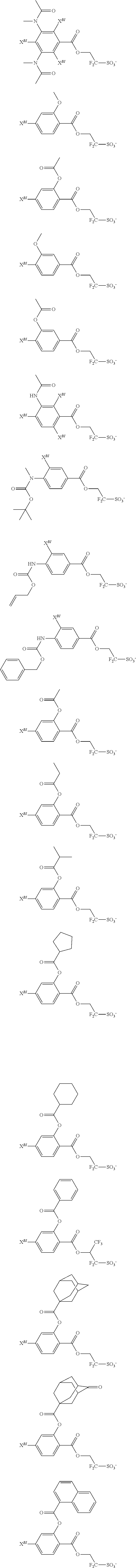

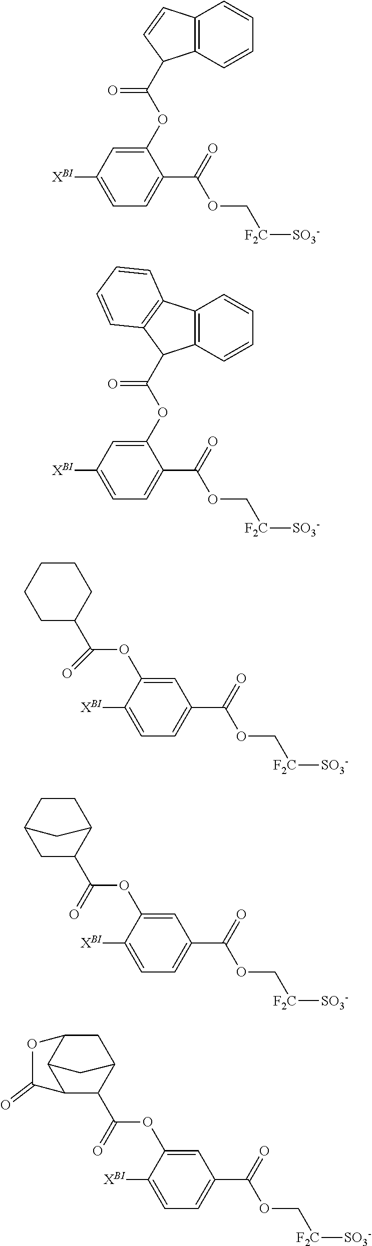

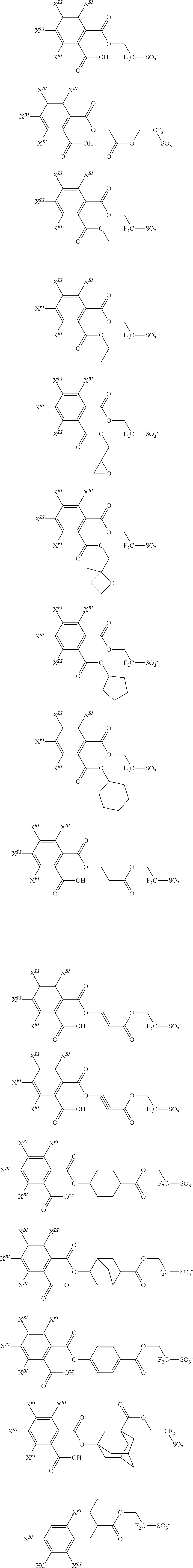

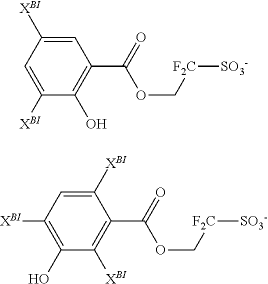

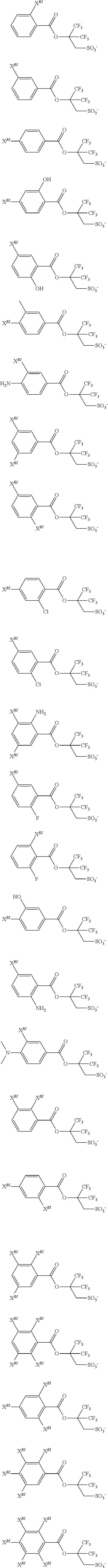

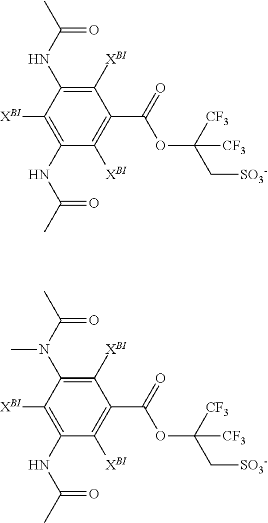

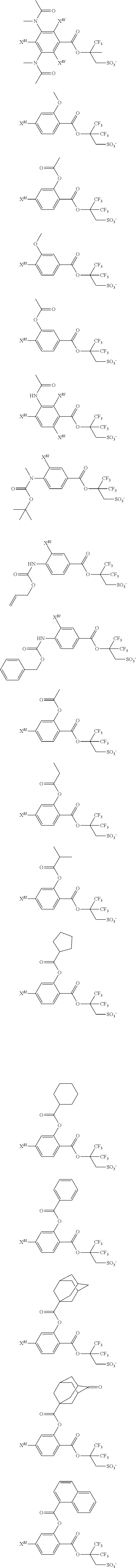

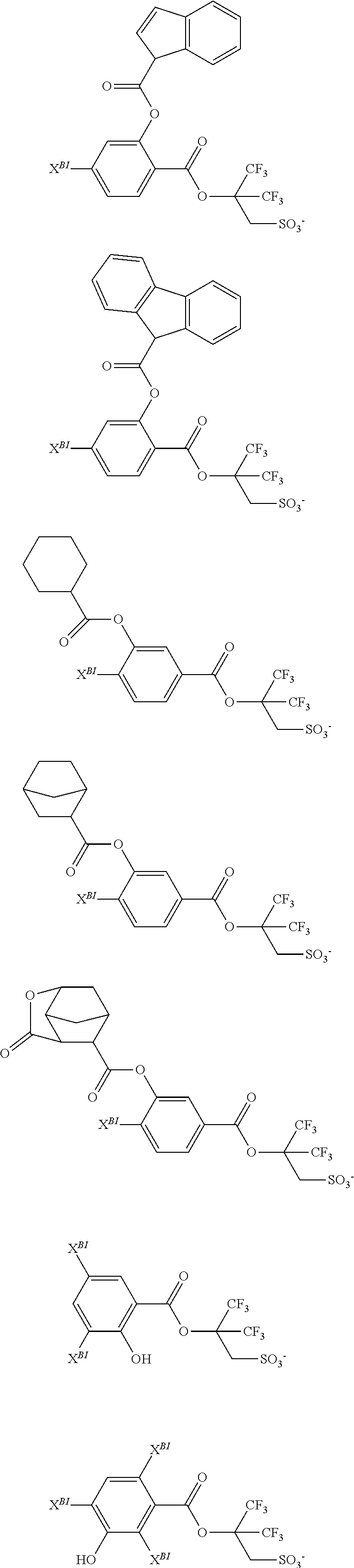

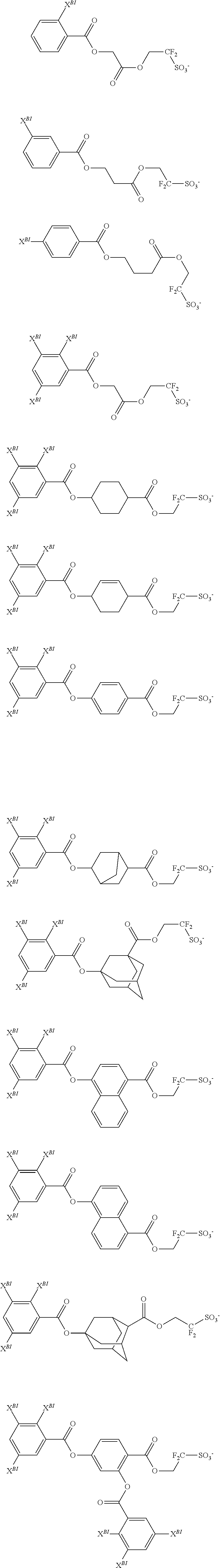

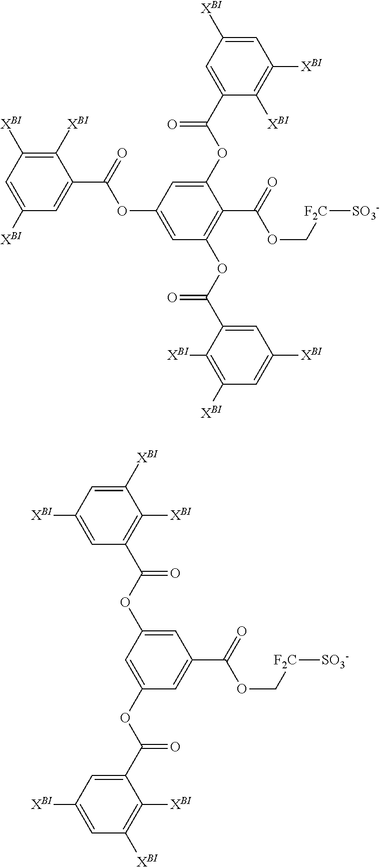

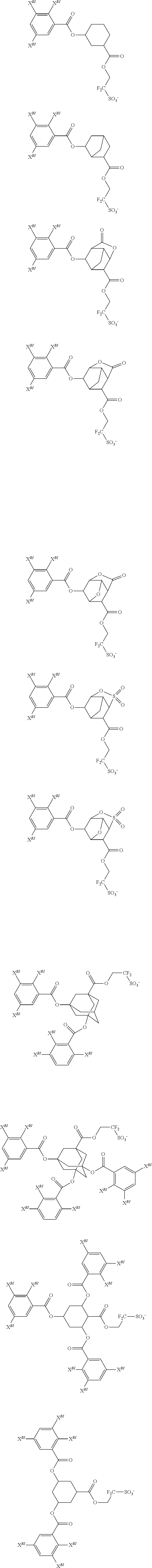

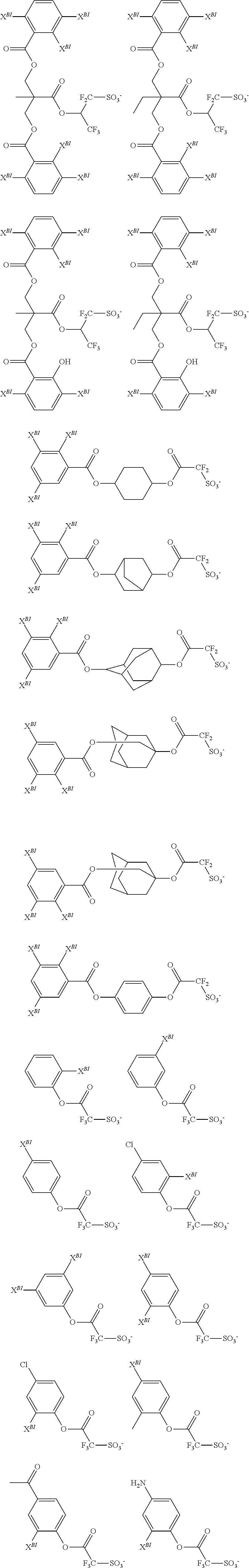

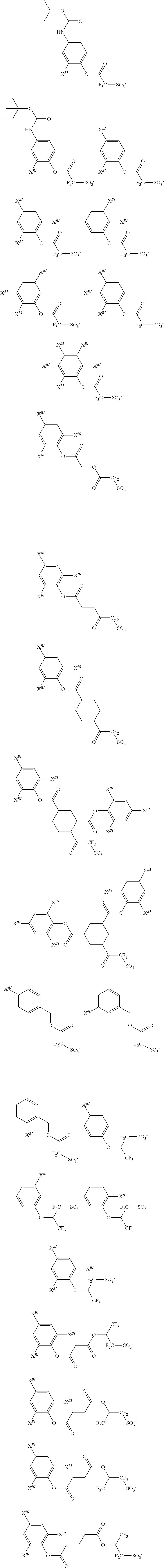

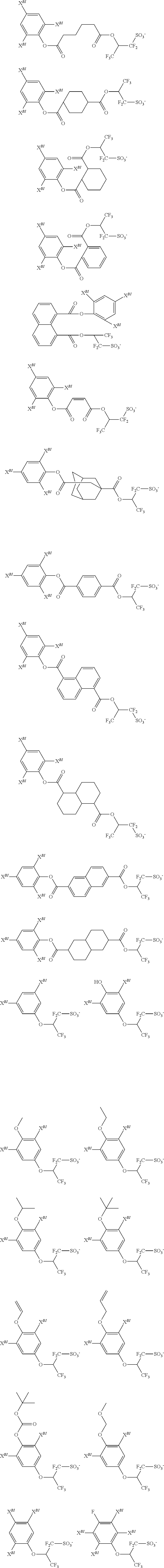

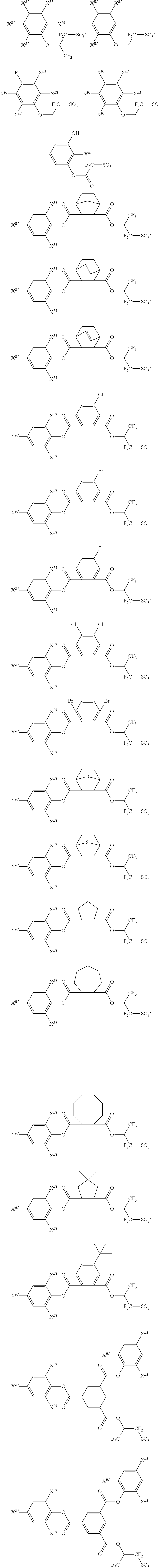

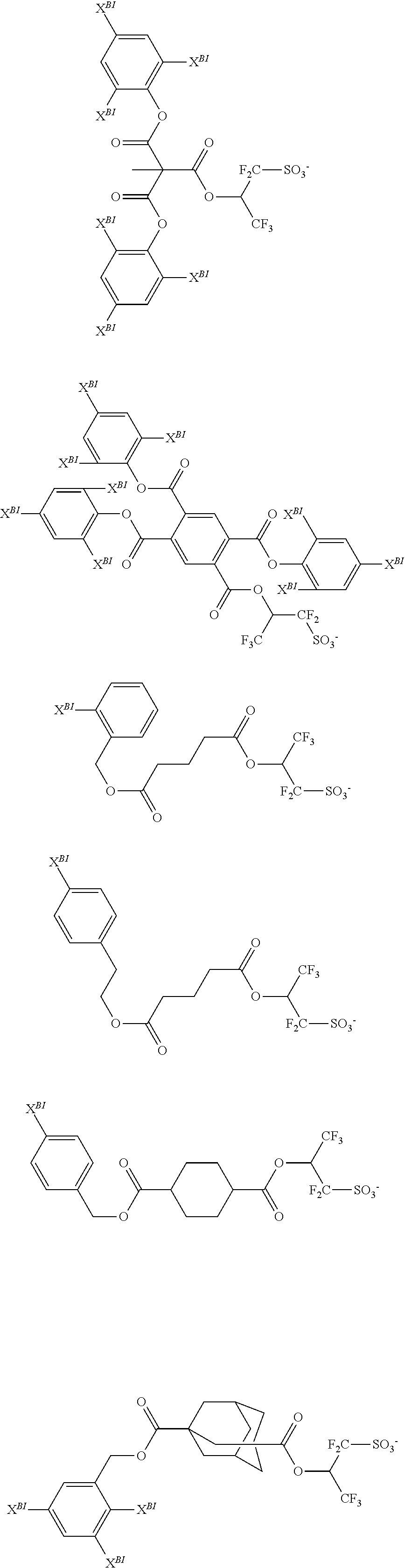

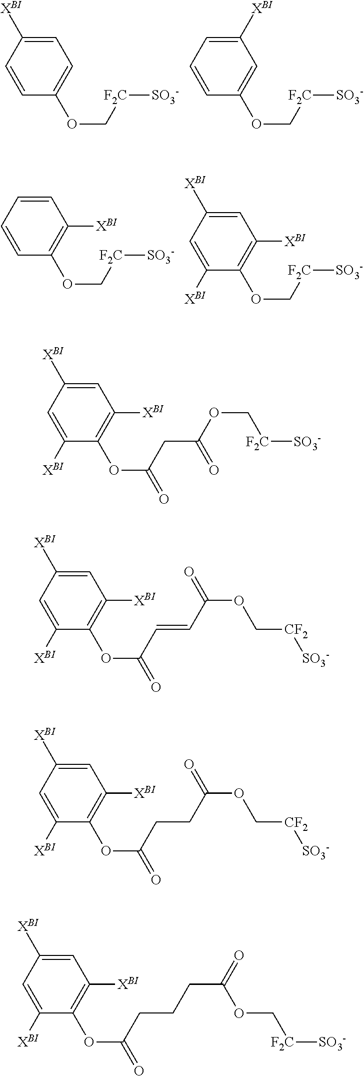

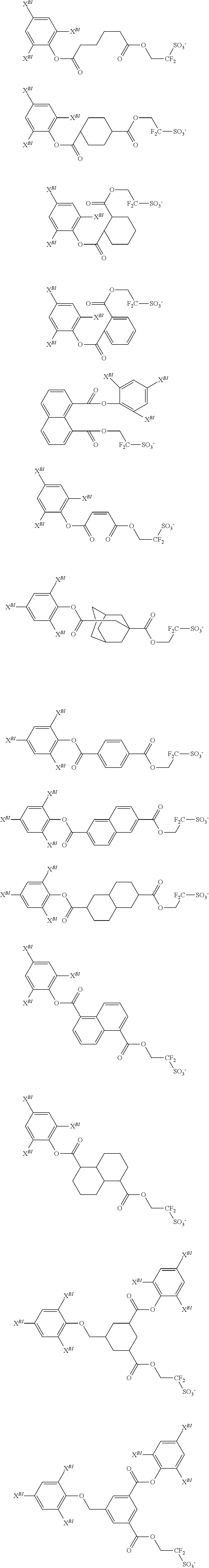

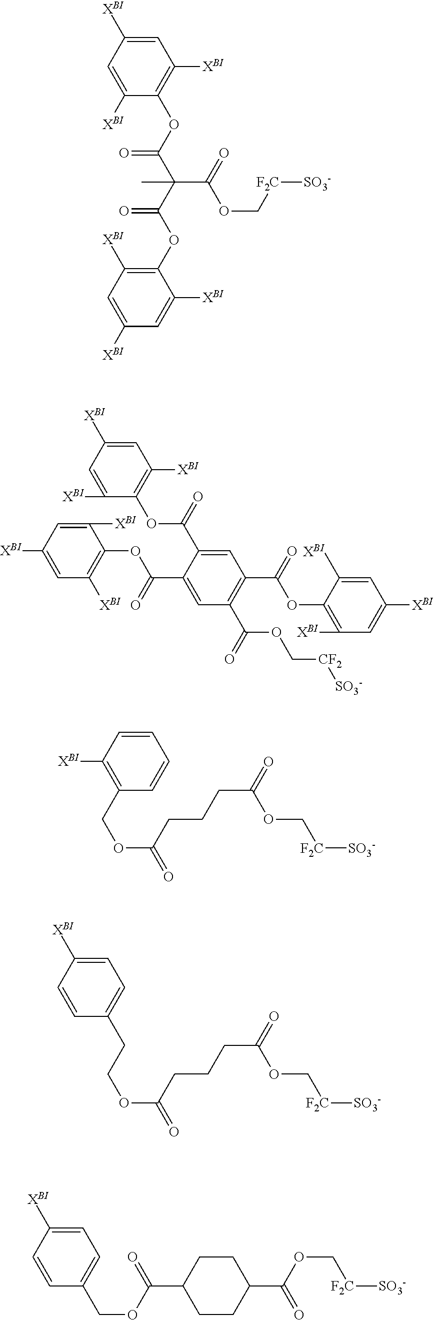

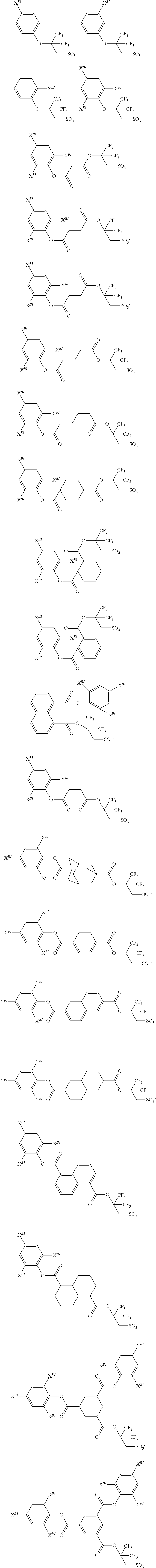

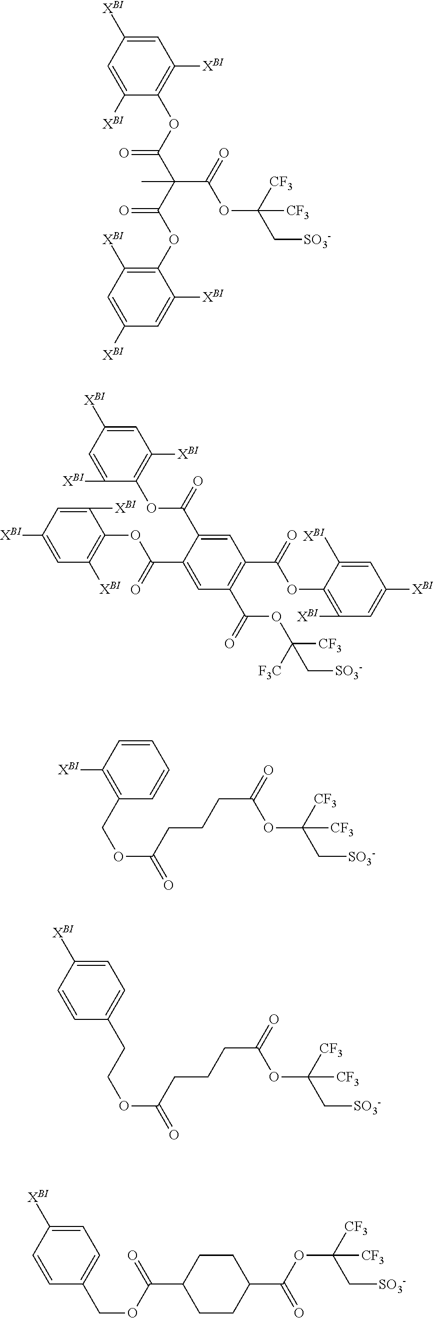

The acid generator of addition type is preferably added to the resist composition of the present invention in an amount of 0.1 to 50 parts by weight, and more preferably 1 to 40 parts by weight per 100 parts by weight of the base polymer. The resist composition of the present invention can function as a chemically amplified resist composition when the base polymer contains any of the repeat units (f1) to (f3) and/or the resist composition contains an acid generator of addition type.

### [Organic Solvent]

The resist composition of the present invention may contain an organic solvent. The organic solvent is not particularly limited as long as the components described above and below are soluble therein. Examples of the organic solvent are described in paragraphs [0144] to [0145] of JP-A 2008-111103, and include ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone.

The organic solvent is preferably added to the resist composition of the present invention in an amount of 100 to 10,000 parts by weight, and more preferably 200 to 8,000 parts by weight per 100 parts by weight of the base polymer. The organic solvent may be used singly or as a mixture of two or more kinds thereof.

### [Other Components]

In addition to the foregoing components, the resist composition of the present invention may contain a surfactant, a dissolution inhibitor, a crosslinker, a quencher other than the sulfonium salt having formula (1) (hereinafter, the quencher is referred to as additional quencher), a water repellency improver, and an acetylene alcohol.

Examples of the surfactant include those described in paragraphs [0165] to [0166] of JP-A 2008-111103. Addition of a surfactant enables to improve or control the coating characteristics of the resist composition. The surfactant is preferably added to the resist composition of the present invention in an amount of 0.0001 to 10 parts by weight per 100 parts by weight of the base polymer. The surfactant may be used singly or in combination of two or more kinds thereof.

In the embodiment in which the resist composition of the present invention is of positive tone, the addition of a dissolution inhibitor may lead to an increased difference in dissolution rate between the exposed region and the unexposed region and a further improvement in resolution. Examples of the dissolution inhibitor include a compound having at least two phenolic hydroxy groups in the molecule, in which 0 to 100 mol % of all the hydrogen atoms in the phenolic hydroxy groups are substituted with acid labile groups, or a compound having at least one carboxy group in the molecule, in which an average of 50 to 100 mol % of all the hydrogen atoms in the carboxy group are substituted with acid labile groups, both the compounds preferably having a molecular weight of 100 to 1,000, and more preferably 150 to 800. Specific examples thereof include bisphenol A, trisphenol, phenolphthalein, cresol novolac, naphthalenecarboxylic acid, adamantanecarboxylic acid, and cholic acid derivatives, in which the hydrogen atom in the hydroxy or carboxy group is substituted with an acid labile group, as described in paragraphs [0155] to [0178] of JP-A 2008-122932.

The dissolution inhibitor is preferably added to the resist composition of positive tone of the present invention in an amount of 0 to 50 parts by weight, and more preferably 5 to 40 parts by weight per 100 parts by weight of the base polymer. The dissolution inhibitor may be used singly or in combination of two or more kinds thereof.

When the resist composition of the present invention is of negative tone, a negative pattern can be obtained by adding a crosslinker to reduce the dissolution rate of a resist film in the exposed region. Examples of the crosslinker include epoxy compounds, melamine compounds, guanamine compounds, glycoluril compounds, and urea compounds having substituted thereon at least one group selected from a methylol group, an alkoxymethyl group, and an acyloxymethyl group, isocyanate compounds, azide compounds, and compounds having a double bond such as an alkenyloxy group. These compounds may be used as an additive or introduced into a polymer side chain as a pendant group. In addition, a compound containing a hydroxy group can also be used as a crosslinker.

Examples of the epoxy compound include tris(2,3-epoxypropyl) isocyanurate, trimethylolmethane triglycidyl ether, trimethylolpropane triglycidyl ether, and triethylolethane triglycidyl ether.

Examples of the melamine compound include hexamethylol melamine, hexamethoxymethyl melamine, hexamethylol melamine compounds having 1 to 6 methylol groups methoxymethylated and mixtures thereof, hexamethoxyethyl melamine, hexaacyloxymethyl melamine, and hexamethylol melamine compounds having 1 to 6 methylol groups acyloxymethylated and mixtures thereof.

Examples of the guanamine compound include tetramethylol guanamine, tetramethoxymethyl guanamine, tetramethylol guanamine compounds having 1 to 4 methylol groups methoxymethylated and mixtures thereof, tetramethoxyethyl guanamine, tetraacyloxyguanamine, and tetramethylol guanamine compounds having 1 to 4 methylol groups acyloxymethylated and mixtures thereof.

Examples of the glycoluril compound include tetramethylol glycoluril, tetramethoxy glycoluril, tetramethoxymethyl glycoluril, tetramethylol glycoluril compounds having 1 to 4 methylol groups methoxymethylated and mixtures thereof, and tetramethylol glycoluril compounds having 1 to 4 methylol groups acyloxymethylated and mixtures thereof. Examples of the urea compound include tetramethylol urea, tetramethoxymethyl urea, tetramethylol urea compounds having 1 to 4 methylol groups methoxymethylated and mixtures thereof, and tetramethoxyethyl urea.

Examples of the isocyanate compound include tolylene diisocyanate, diphenylmethane diisocyanate, hexamethylene diisocyanate, and cyclohexane diisocyanate.

Examples of the azide compound include 1,1′-biphenyl-4,4′-bisazide, 4,4′-methylidenebisazide, and 4,4′-oxybisazide.

Examples of the alkenyloxy group-containing compound include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylol propane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylol propane trivinyl ether.

The crosslinker is preferably added to the resist composition of negative tone of the present invention in an amount of 0.1 to 50 parts by weight, and more preferably 1 to 40 parts by weight per 100 parts by weight of the base polymer. The crosslinker may be used singly or in combination of two or more kinds thereof.

Examples of the additional quencher include conventional basic compounds. Examples of the conventional basic compounds include primary, secondary, and tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, imide derivatives, and carbamate derivatives. In particular, primary, secondary, and tertiary amine compounds described in paragraphs [0146] to [0164] of JP-A 2008-111103, particularly amine compounds having a hydroxy group, an ether bond, an ester bond, a lactone ring, a cyano group, or a sulfonic ester bond, and compounds having a carbamate group described in JP 3790649 are preferred. Addition of a basic compound may be effective for further reducing the diffusion rate of the acid in the resist film or correcting the pattern profile.

Examples of the additional quencher also include onium salts such as sulfonium salts, iodonium salts, and ammonium salts of sulfonic acids which are not fluorinated at the α-position, or carboxylic acids, as described in JP-A 2008-158339. While a sulfonic acid which is fluorinated at the α-position, an imide acid, or a methide acid is necessary for deprotecting the acid labile group of a carboxylic acid ester, an α-non-fluorinated sulfonic acid or a carboxylic acid is released by salt exchange with an α-non-fluorinated onium salt. The α-non-fluorinated sulfonic acid and carboxylic acid function as a quencher because they do not induce a deprotection reaction.

Examples of the additional quencher further include a polymeric quencher described in JP-A 2008-239918. The polymeric quencher segregates at the resist film surface and thus enhances the rectangularity of the resist pattern. When a protective film is applied as is often the case in immersion lithography, the polymeric quencher is also effective for preventing a film thickness loss of the resist pattern or rounding of the pattern top.

The additional quencher is preferably added to the resist composition of the present invention in an amount of 0 to 5 parts by weight, and more preferably 0 to 4 parts by weight per 100 parts by weight of the base polymer. The additional quencher may be used singly or in combination of two or more kinds thereof.

The water repellency improver improves the water repellency of the surface of the resist film, and can be used in the topcoatless immersion lithography. Examples of preferred water repellency improvers include polymers having a fluoroalkyl group and polymers having a specific structure with a 1,1,1,3,3,3-hexafluoro-2-propanol residue, and those described in JP-A 2007-297590 and JP-A 2008-111103, for example, are more preferred. The water repellency improver should be soluble in alkaline developers and organic solvent developers. The water repellency improver having a specific structure with a 1,1,1,3,3,3-hexafluoro-2-propanol residue is well soluble in the developer. A polymer having an amino group or amine salt copolymerized as repeat units may serve as the water repellency improver and is effective for preventing evaporation of the acid during PEB, thus preventing any hole pattern opening failure after development. The water repellency improver is preferably added to the resist composition of the present invention in an amount of 0 to 20 parts by weight, and more preferably 0.5 to 10 parts by weight per 100 parts by weight of the base polymer. The water repellency improver may be used singly or in combination of two or more kinds thereof.

Examples of the acetylene alcohol include those described in paragraphs [0179] to [0182] of JP-A 2008-122932. The acetylene alcohol is preferably added to the resist composition of the present invention in an amount of 0 to 5 parts by weight per 100 parts by weight of the base polymer. The acetylene alcohol may be used singly or in combination of two or more kinds thereof.

### [Pattern Forming Process]

The resist composition of the present invention is used in the fabrication of various integrated circuits by a well-known lithography technique. Examples of the pattern forming process include a process including the steps of: applying the resist composition onto a substrate to form a resist film on the substrate, exposing the resist film to high-energy radiation, and developing the exposed resist film in a developer.

The resist composition of the present invention is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying, or doctor coating so that the coating may have a thickness of 0.01 to 2 μm. The coating is prebaked on a hotplate preferably at a temperature of 60 to 150° C. for 10 seconds to 30 minutes, and more preferably at 80 to 120° C. for 30 seconds to 20 minutes to form a resist film.

The resist film is then exposed to high-energy radiation such as UV, deep-UV, EB, EUV having a wavelength of 3 to 15 nm, X-rays, soft X-rays, excimer laser, 7-rays, or synchrotron radiation. When UV, deep-UV, EUV, X-rays, soft X-rays, excimer laser, 7-rays, or synchrotron radiation is used as the high-energy radiation, the resist film is exposed thereto directly or through a mask having a desired pattern preferably at a dose of about 1 to 200 mJ/cm², and more preferably about 10 to 100 mJ/cm². When EB is used as the high-energy radiation, the resist film is exposed thereto directly or through a mask having a desired pattern preferably at a dose of about 0.1 to 300 μC/cm², and more preferably about 0.5 to 200 μC/cm². It is appreciated that the resist composition of the present invention is suitable for micropatterning using high-energy radiation such as KrF excimer laser, ArF excimer laser, EB, EUV, X-rays, soft X-rays, T-rays, or synchrotron radiation, especially for micropatterning using EB or EUV.

After the exposure, the resist film may be baked (PEB) on a hotplate or in an oven preferably at 30 to 150° C. for 10 seconds to 30 minutes, and more preferably at 50 to 120° C. for 30 seconds to 20 minutes.

After the exposure or PEB, the resist film is developed in a developer in the form of an alkaline aqueous solution for 3 seconds to 3 minutes, preferably 5 seconds to 2 minutes by conventional techniques such as dip, puddle, and spray techniques to form a desired pattern. A preferred developer is a 0.1 to 10 wt %, preferably 2 to 5 wt % aqueous solution of tetramethylammonium hydroxide (TMAH), tetraethylammonium hydroxide, tetrapropylammonium hydroxide, or tetrabutylammonium hydroxide. In the case of a positive resist composition, the resist film in the exposed region is dissolved in the developer whereas the resist film in the unexposed region is not dissolved. In this way, the desired positive pattern is formed on the substrate. In the case of a negative resist composition, inversely the resist film in the exposed region is insolubilized in the developer whereas the resist film in the unexposed region is dissolved.

A negative pattern can be obtained from the positive resist composition containing a base polymer containing an acid labile group by effecting organic solvent development. Examples of the developer used herein include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. The organic solvent may be used singly or as a mixture of two or more kinds thereof.

At the end of development, the resist film is rinsed. The rinsing liquid is preferably a solvent which is miscible with the developer and does not dissolve the resist film. Examples of preferred solvents include alcohols having 3 to 10 carbon atoms, ether compounds having 8 to 12 carbon atoms, alkanes, alkenes, and alkynes each having 6 to 12 carbon atoms, and aromatic solvents.

Examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the alkenes having 6 to 12 carbon atoms include hexene, heptene, octene, cyclohexene, methylcyclohexene, dimethylcyclohexene, cycloheptene, and cyclooctene. Examples of the alkynes having 6 to 12 carbon atoms include hexyne, heptyne, and octyne.

Examples of the aromatic solvents include toluene, xylene, ethylbenzene, isopropylbenzene, tert-butylbenzene, and mesitylene.

Rinsing is effective for reducing the resist pattern collapse and defect formation. However, rinsing is not essential. If rinsing is omitted, the amount of solvent used may be reduced.

A hole or trench pattern after development may be shrunk by the thermal flow, RELACS®, or DSA process. A hole pattern is shrunk by applying a shrink agent thereto, and baking the resist composition such that the shrink agent may undergo crosslinking at the resist film surface due to diffusion of the acid catalyst from the resist film during baking, and the shrink agent may attach to the sidewall of the hole pattern. The baking temperature is preferably 70 to 180° C., more preferably 80 to 170° C., and the baking time is preferably 10 to 300 seconds to remove the excess shrink agent and shrink the hole pattern.

### EXAMPLES

Hereinafter, the present invention is specifically described with reference to a Synthesis Example, Examples, and Comparative Examples, but the present invention is not limited to the following Examples.

Structures of the quenchers Q-1 to Q-23 used in the resist compositions are shown below.

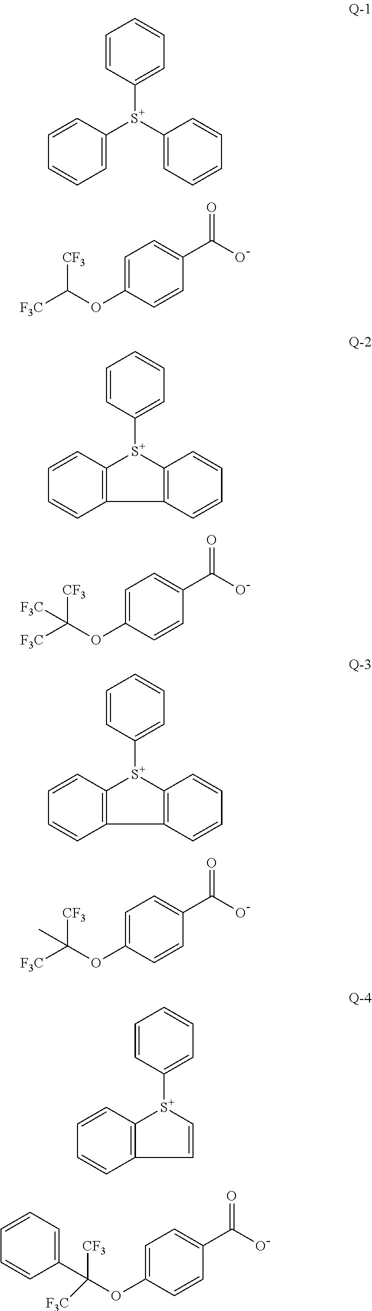

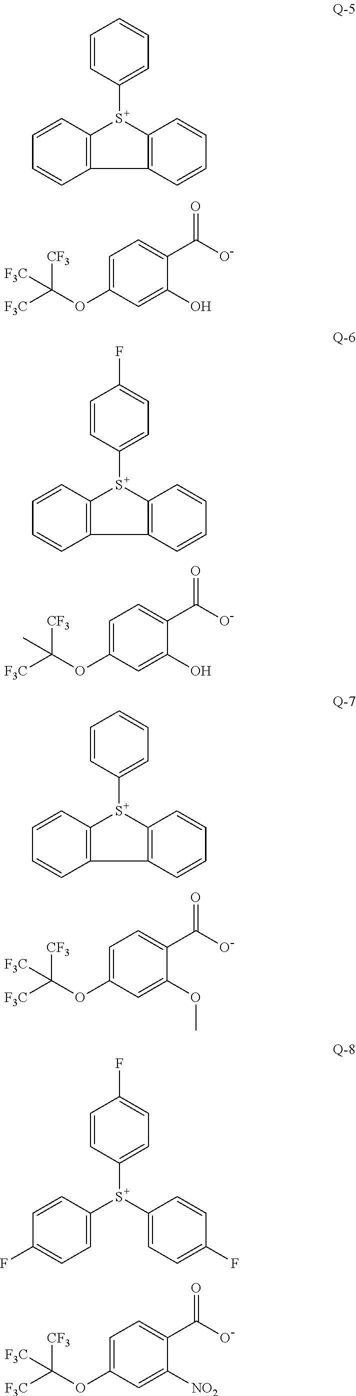

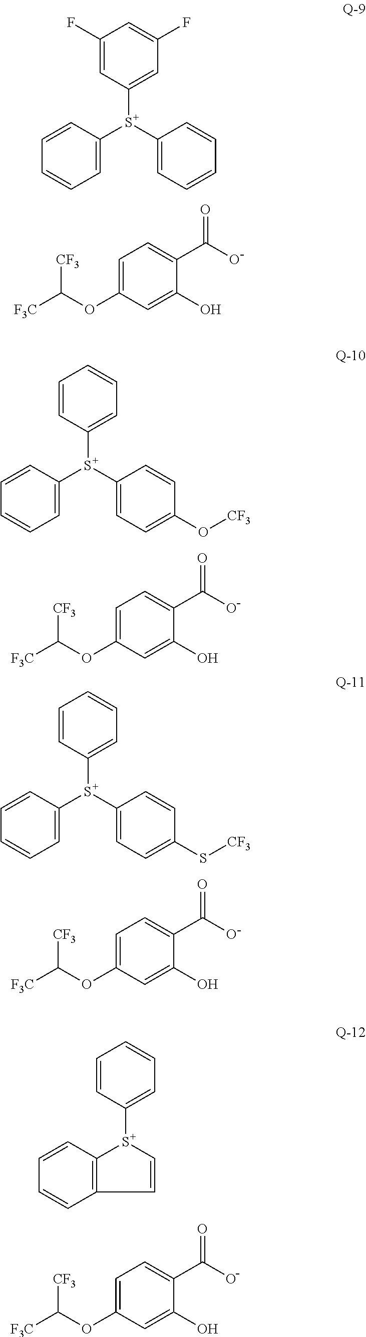

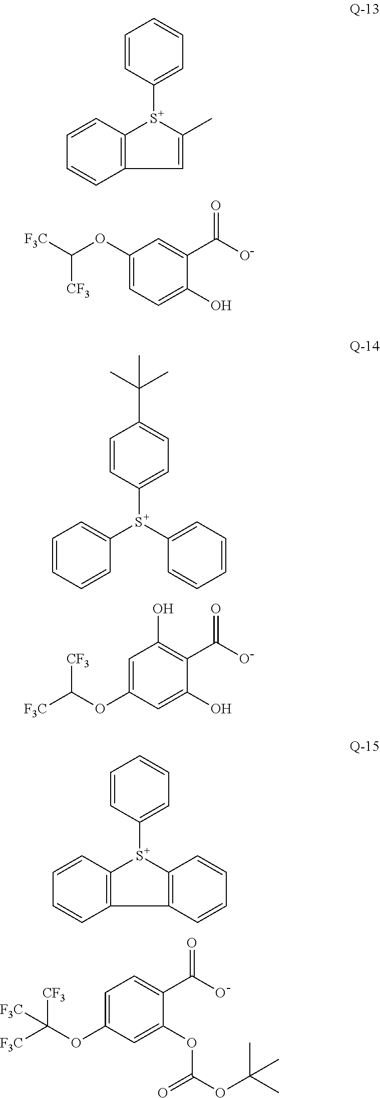

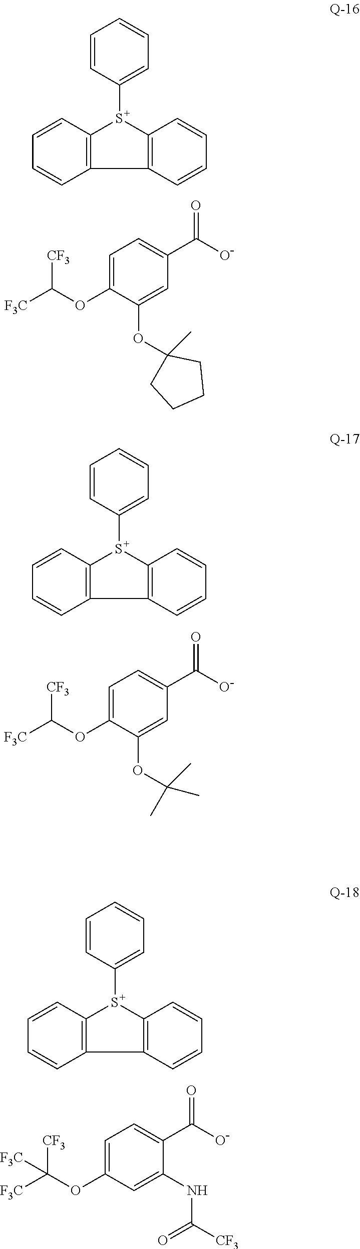

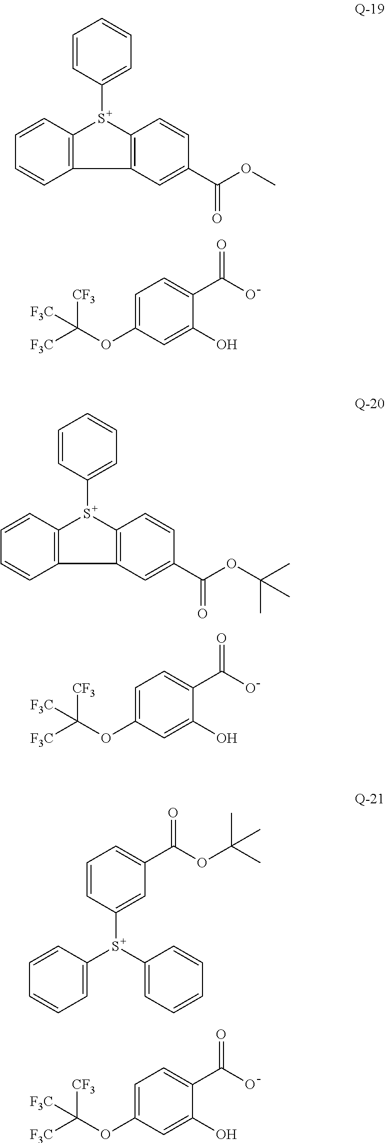

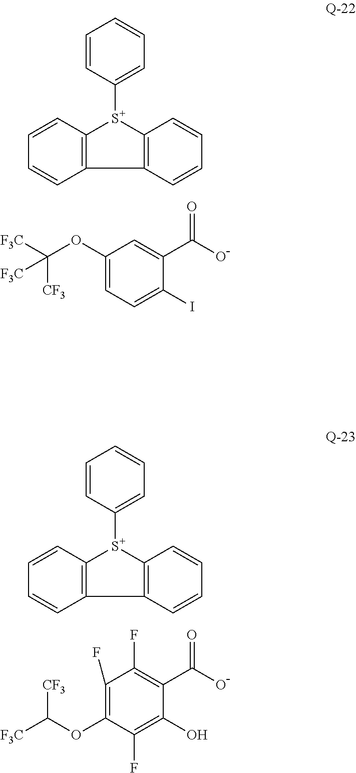

### [Synthesis Example] Synthesis of Base Polymers (Polymers P-1 to P-5)

Base polymers (polymers P-1 to P-5) each having the composition shown below were synthesized by combining monomers, effecting a copolymerization reaction in a THF solvent, pouring the reaction solution into methanol, washing the solid precipitate with hexane, isolation, and drying. The base polymers were analyzed for composition by ¹H-NMR spectroscopy and for Mw and Mw/Mn by GPC versus polystyrene standards using a THF solvent.

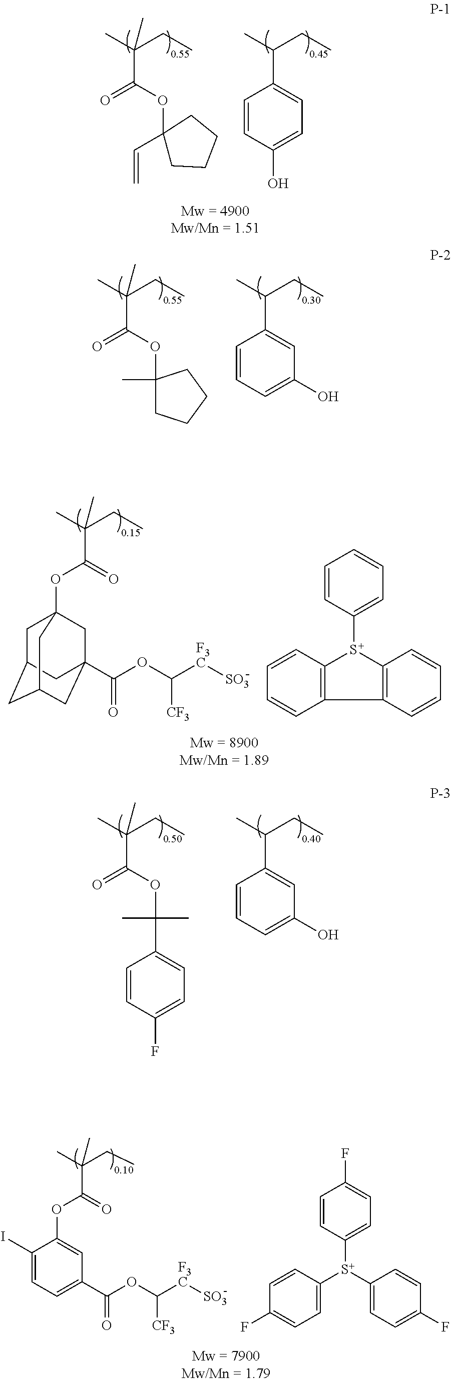

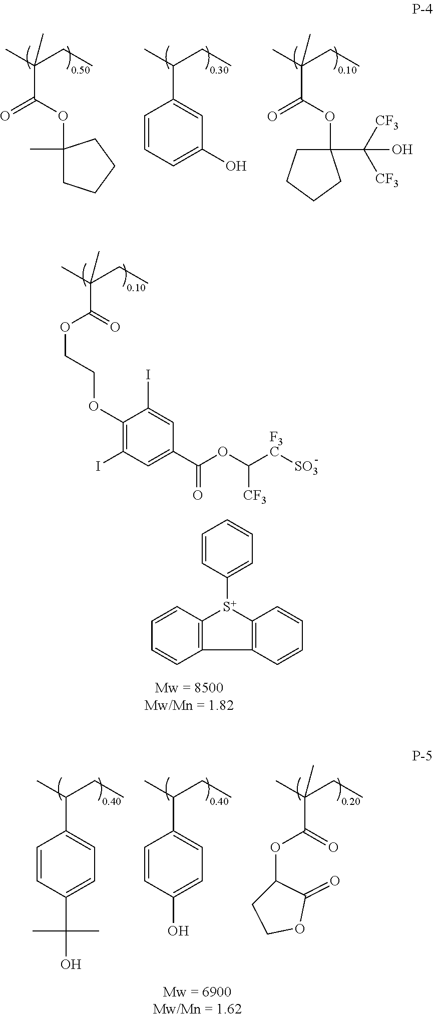

### [Examples 1 to 27 and Comparative Examples 1 to 4] Preparation and Evaluation of Resist Compositions

### (1) Preparation of Resist Compositions

A solution obtained by dissolving the components according to the composition shown in Table 1 was filtered through a 0.2 μm filter to prepare a resist composition. The resist compositions of Examples 1 to 26 and Comparative Examples 1 to 3 were of positive tone, and the resist compositions of Example 27 and Comparative Example 4 were of negative tone.

The components in Table 1 are as follows.

### Organic Solvents:

PGMEA (propylene glycol monomethyl ether acetate)
DAA (diacetone alcohol)
EL (ethyl lactate)

### Acid Generators: PAG-1 to PAG-5

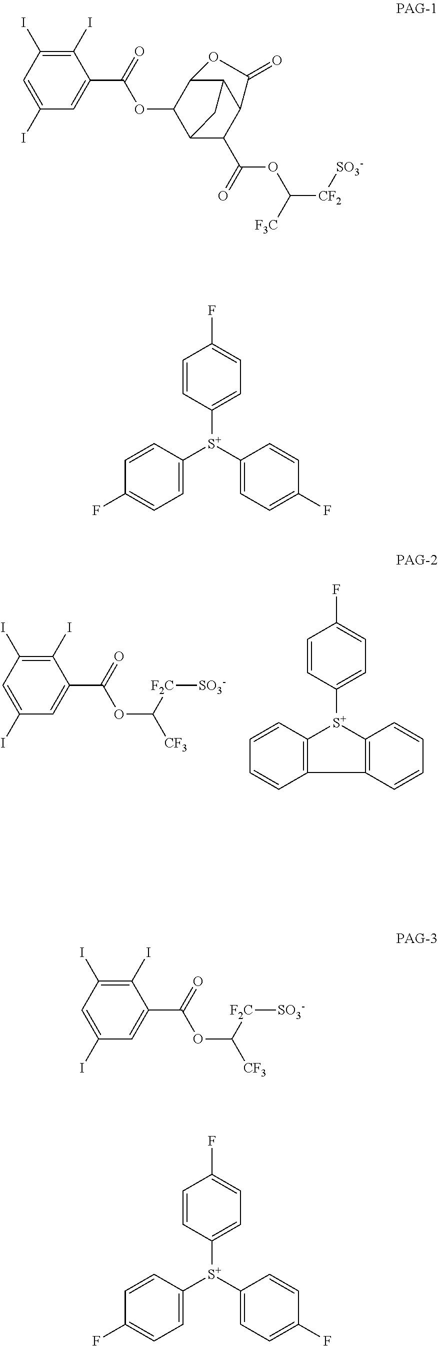

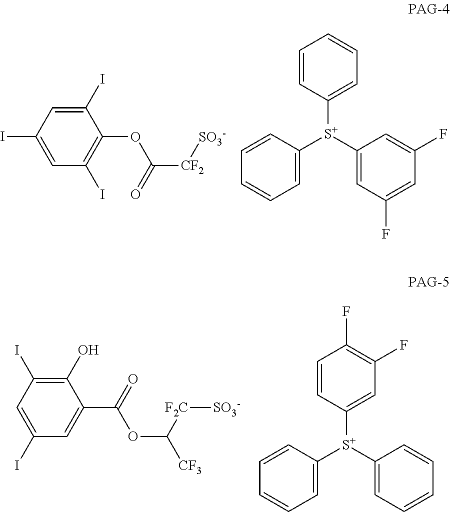

Blended Quenchers: bQ-1 and bQ-2

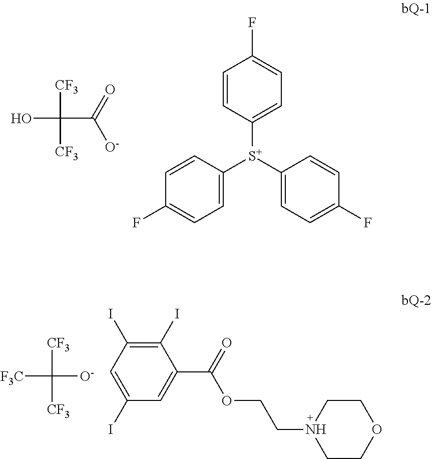 [SMILES: O=C([O-])C(O)(C(F)(F)F)C(F)(F)F ; Fc1ccc([S+](c2ccc(F)cc2)c2ccc(F)cc2)cc1 ; [O-]C(C(F)(F)F)(C(F)(F)F)C(F)(F)F ; O=C(OCCN1CCOCC1)c1cc(I)cc(I)c1I]

Comparative Quenchers: cQ-1 to cQ-3

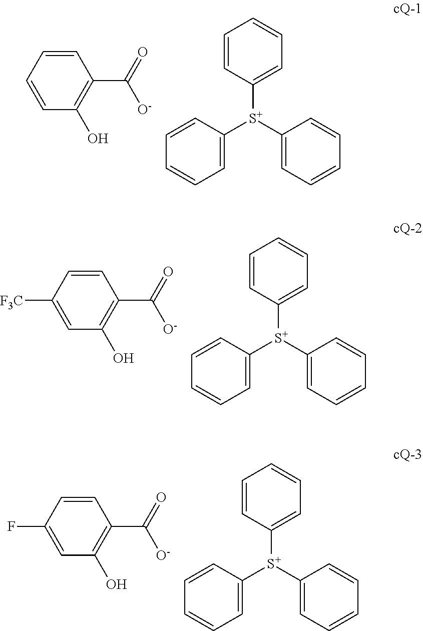 [SMILES: O=C([O-])c1ccccc1O ; c1ccc([S+](c2ccccc2)c2ccccc2)cc1 ; O=C([O-])c1ccc(C(F)(F)F)cc1O ; c1ccc([S+](c2ccccc2)c2ccccc2)cc1 ; O=C([O-])c1ccc(F)cc1O ; c1ccc([S+](c2ccccc2)c2ccccc2)cc1]

### (2) EUV Lithography Evaluation

Each of the resist compositions shown in Tables 1 and 2 was applied by spin coating to a silicon substrate having a 20-nm coating of silicon-containing spin-on hard mask SHB-A940 (Shin-Etsu Chemical Co., Ltd., Si content 43 wt %) and prebaked on a hotplate at 100° C. for 60 seconds to form a 60 nm-thick resist film. Then, using an EUV scanner NXE3400 (ASML, NA 0.33, a 0.9/0.6, quadrupole illumination), the resist film was exposed to EUV through a mask bearing a hole pattern at a pitch of 44 nm (on-wafer size) and +20% bias. The resist film was baked (PEB) on a hotplate at the temperature shown in Table 1 for 60 seconds and developed in a 2.38 wt % TMAH aqueous solution for 30 seconds to form a hole pattern having a size of 22 nm in Examples 1 to 25 and Comparative Examples 1 to 3, and a dot pattern having a size of 22 nm in Example 26 and Comparative Example 4.

The resist pattern was observed under CD-SEM (CG6300, Hitachi High-Technologies Corp.). The exposure dose that provides a hole pattern or a dot pattern each having a size of 22 nm was reported as sensitivity. The size of 50 holes or dots printed at that dose was measured, from which a 3-fold value (3a) of the standard deviation (a) was computed and reported as CDU. The results are collectively shown in Tables 1 and 2.

TABLE 1

| | | | Acid | | | | | |
|---|---|---|---|---|---|---|---|---|
| | | Polymer | generator | Quencher | Organic solvent | PEB temp. | Sensitivity | CDU |
| | | (pbw) | (pbw) | (pbw) | (pbw) | (° C.) | (mJ/cm²) | (nm) |
| Example | 1 | P-1 | PAG-1 | Q-1 | PGMEA (3,000) | 80 | 33 | 3.2 |
| | | (100) | (30.2) | (5.50) | DAA (500) | | | |
| | 2 | P-1 | PAG-2 | Q-2 | PGMEA (3,000) | 80 | 30 | 3.0 |
| | | (100) | (24.8) | (6.16) | DAA (500) | | | |
| | 3 | P-1 | PAG-2 | Q-3 | PGMEA (3,000) | 80 | 32 | 3.2 |
| | | (100) | (24.8) | (5.62) | DAA (500) | | | |
| | 4 | P-1 | PAG-2 | Q-4 (2.87) | PGMEA (3,000) | 80 | 33 | 3.2 |
| | | (100) | (24.8) | bQ-1 (2.64) | DAA (500) | | | |
| | 5 | P-1 | PAG-2 | Q-5 | PGMEA (3,000) | 80 | 29 | 3.0 |
| | | (100) | (24.8) | (6.32) | DAA (500) | | | |
| | 6 | P-1 | PAG-2 | Q-6 | PGMEA (3,000) | 80 | 31 | 3.2 |
| | | (100) | (24.8) | (5.96) | DAA (500) | | | |
| | 7 | P-1 | PAG-2 | Q-7 | PGMEA (3,000) | 80 | 30 | 3.0 |
| | | (100) | (24.8) | (6.46) | DAA (500) | | | |
| | 8 | P-1 | PAG-2 | Q-8 | PGMEA (3,000) | 80 | 31 | 3.1 |
| | | (100) | (24.8) | (7.17) | DAA (500) | | | |
| | 9 | P-1 | PAG-3 | Q-9 (3.01) | PGMEA (3,000) | 80 | 30 | 3.2 |
| | | (100) | (25.7) | bQ-2 (4.24) | DAA (500) | | | |
| | 10 | P-1 | PAG-3 | Q-10 | PGMEA (3,000) | 80 | 29 | 3.2 |
| | | (100) | (25.7) | (6.50) | DAA (500) | | | |
| | 11 | P-1 | PAG-3 | Q-11 | PGMEA (3,000) | 80 | 31 | 3.3 |
| | | (100) | (25.7) | (6.66) | DAA (500) | | | |
| | 12 | P-1 | PAG-3 | Q-12 | EL (3,000) | 80 | 29 | 3.2 |
| | | (100) | (25.7) | (5.14) | DAA (500) | | | |
| | 13 | P-1 | PAG-3 | Q-13 | EL | 80 | 30 | 3.2 |
| | | (100) | (25.7) | (5.28) | (3,500) | | | |
| | 14 | P-1 | PAG-3 | Q-14 | PGMEA (3,000) | 80 | 30 | 3.3 |
| | | (100) | (25.7) | (6.38) | DAA (500) | | | |
| | 15 | P-1 | PAG-3 | Q-15 | PGMEA (3,000) | 80 | 32 | 3.2 |
| | | (100) | (25.7) | (7.32) | DAA (500) | | | |
| | 16 | P-1 | PAG-3 | Q-16 | PGMEA (3,000) | 80 | 33 | 3.2 |
| | | (100) | (25.7) | (6.46) | DAA (500) | | | |
| | 17 | P-1 | PAG-4 | Q-17 | PGMEA (3,000) | 80 | 33 | 3.2 |
| | | (100) | (23.2) | (6.20) | DAA (500) | | | |
| | 18 | P-1 | PAG-4 | Q-18 | PGMEA (3,000) | 80 | 32 | 3.2 |
| | | (100) | (23.2) | (7.27) | DAA (500) | | | |
| | 19 | P-1 | PAG-4 | Q-19 | PGMEA (3,000) | 80 | 29 | 3.2 |
| | | (100) | (23.2) | (6.90) | DAA (500) | | | |
| | 20 | P-1 | PAG-4 | Q-20 | PGMEA (3,000) | 80 | 29 | 3.0 |
| | | (100) | (23.2) | (7.32) | DAA (500) | | | |
| | 21 | P-1 | PAG-4 | Q-21 | PGMEA (3,000) | 80 | 30 | 3.2 |
| | | (100) | (23.2) | (7.34) | DAA (500) | | | |
| | 22 | P-1 | PAG-4 | Q-22 | PGMEA (3,000) | 80 | 31 | 3.2 |
| | | (100) | (23.2) | (7.42) | DAA (500) | | | |
| | 23 | P-1 | PAG-4 | Q-23 | PGMEA (3,000) | 80 | 32 | 3.2 |
| | | (100) | (23.2) | (6.18) | DAA (500) | | | |
| | 24 | P-2 | — | Q-5 | PGMEA (3,000) | 80 | 34 | 3.0 |
| | | (100) | | (6.32) | DAA (500) | | | |
| | 25 | P-3 | — | Q-5 | PGMEA (3,000) | 80 | 32 | 2.9 |
| | | (100) | | (6.32) | DAA (500) | | | |
| | 26 | P-4 | — | Q-5 | PGMEA (3,000) | 80 | 31 | 3.0 |
| | | (100) | | (6.32) | DAA (500) | | | |
| | 27 | P-5 | PAG-5 | Q-5 | PGMEA (3,000) | 110 | 35 | 3.7 |
| | | (100) | (20) | (6.32) | DAA (500) | | | |

TABLE 2

| | | | Acid | | | | | |
|---|---|---|---|---|---|---|---|---|
| | | Polymer | generator | Quencher | Organic solvent | PEB temp. | Sensitivity | CDU |
| | | (pbw) | (pbw) | (pbw) | (pbw) | (° C.) | (mJ/cm²) | (nm) |
| Comparative | 1 | P-1 | PAG-2 | cQ-1 | PGMEA (3,000) | 80 | 43 | 4.2 |
| Example | | (100) | (24.8) | (4.00) | DAA (500) | | | |
| | 2 | P-1 | PAG-2 | cQ-2 | PGMEA (3,000) | 80 | 38 | 3.8 |
| | | (100) | (24.8) | (4.52) | DAA (500) | | | |
| | 3 | P-1 | PAG-2 | cQ-3 | PGMEA (3,000) | 80 | 37 | 3.7 |
| | | (100) | (24.8) | (4.18) | DAA (500) | | | |
| | 4 | P-5 | PAG-5 | cQ-1 | PGMEA (3,000) | 110 | 46 | 5.0 |
| | | (100) | (20) | (4.00) | DAA (500) | | | |

From the results shown in Tables 1 and 2, it was found that the resist composition of the present invention containing a sulfonium salt of a benzoic acid which is substituted with a C₂-C₁₄ hydrocarbyloxy group having a trifluoromethyl group exhibits higher sensitivity and improved CDU.

Japanese Patent Application No. 2023-034211 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a quencher containing a sulfonium salt of a benzoic acid which is substituted with a C₂-C₁₄ hydrocarbyloxy group having a trifluoromethyl group.

2. The resist composition of claim 1, wherein the sulfonium salt has formula (1): 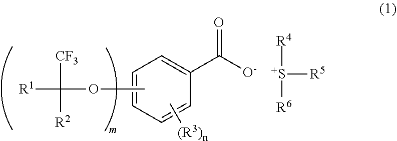
wherein m is 1 or 2, and n is an integer of 0 to 2,
R¹ is a hydrogen atom, a C₁-C₁₂ aliphatic hydrocarbyl group, or a C₆-C₁₀ aryl group, some or all of hydrogen atoms of the aliphatic hydrocarbyl group and the aryl group may be substituted with a halogen atom, a trifluoromethyl group, or a trifluoromethoxy group, and some of —CH₂— of the aliphatic hydrocarbyl group may be substituted with an ether bond or an ester bond,
R² is a hydrogen atom, a C₁-C₄ alkyl group, or a trifluoromethyl group,
R³ is a halogen atom, a trifluoromethyl group, a cyano group, a nitro group, a hydroxy group, a C₁-C₁₂ hydrocarbyloxy group, a C₂-C₁₂ hydrocarbyloxycarbonyl group, a C₂-C₁₂ hydrocarbylcarbonyloxy group, a C₂-C₁₂ hydrocarbyloxycarbonyloxy group, or a substituted or unsubstituted amino group, and
R⁴ to R⁶ are each independently a halogen atom or a C₁-C₂₀ hydrocarbyl group which may contain a heteroatom, and R⁴ and R⁵ may bond together to form a ring with a sulfur atom to which they are bonded.

3. The resist composition of claim 1, further comprising a base polymer.

4. The resist composition of claim 3, wherein the base polymer contains repeat units having formula (a1) or repeat units having formula (a2): 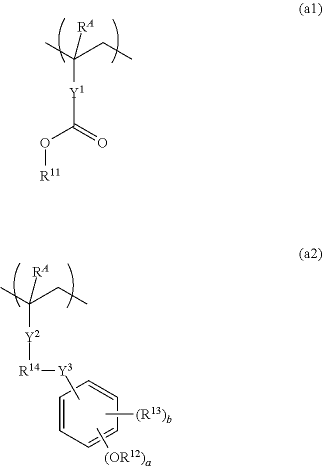
wherein R^{A} is each independently a hydrogen atom or a methyl group,
Y¹ is a single bond, a phenylene group, a naphthylene group, or a C₁-C₁₂ linking group containing at least one moiety selected from an ester bond and a lactone ring,
Y² is a single bond or an ester bond,
Y³ is a single bond, an ether bond, or an ester bond,
R¹¹ and R¹² are each independently an acid labile group,
R¹³ is a fluorine atom, a trifluoromethyl group, a cyano group, or a C₁-C₆ saturated hydrocarbyl group,
R¹⁴ is a single bond or a C₁-C₆ alkanediyl group in which some constituent —CH₂— may be substituted with an ether bond or an ester bond, and
a is 1 or 2, and b is an integer of 0 to 4, provided that 1≤a+b≤5.

5. The resist composition of claim 4, which is a chemically amplified positive resist composition.

6. The resist composition of claim 3, wherein the base polymer is free of an acid labile group.

7. The resist composition of claim 6, which is a chemically amplified negative resist composition.

8. The resist composition of claim 3, wherein the base polymer contains at least one kind selected from repeat units having formulae (f1) to (f3): 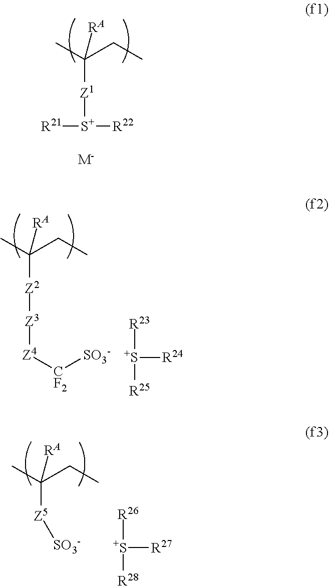
wherein R^{A} is each independently a hydrogen atom or a methyl group,
Z¹ is a single bond, a C₁-C₆ aliphatic hydrocarbylene group, a phenylene group, a naphthylene group, a C₇-C₁₈ group obtained by combining the foregoing, —O—Z¹¹—, —C(═O)—O—Z¹¹—, or —C(═O)—NH—Z¹¹—, wherein Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group,
Z² is a single bond or an ester bond,
Z³ is a single bond, —Z³¹—C(═O)—O—, —Z³¹—O—, or —Z³¹—O—C(═O)—, wherein Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom,
Z⁴ is a methylene group, a 2,2,2-trifluoro-1,1-ethanediyl group, or a carbonyl group,
Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—, wherein Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a halogen atom, or a hydroxy group,
R²¹ to R²⁸ are each independently a halogen atom or a C₁-C₂₀ hydrocarbyl group which may contain a heteroatom, and R²³ and R²⁴ or R²⁶ and R²⁷ may bond together to form a ring with a sulfur atom to which they are bonded, and
M⁻ is a non-nucleophilic counter ion.

9. The resist composition of claim 1, further comprising an acid generator that generates a strong acid.

10. The resist composition of claim 9, wherein the acid generator generates a sulfonic acid, an imide acid, or a methide acid.

11. The resist composition of claim 1, further comprising an organic solvent.

12. The resist composition of claim 1, further comprising a surfactant.

13. A pattern forming process comprising the steps of:
applying the resist composition of claim 1 onto a substrate to form a resist film on the substrate,
exposing the resist film to high-energy radiation, and
developing the exposed resist film in a developer.

14. The pattern forming process of claim 13, wherein the high-energy radiation is KrF excimer laser, ArF excimer laser, electron beam, or extreme ultraviolet having a wavelength of 3 to 15 nm.
